(19) United States
(12) Patent Application Publication
(10) Pub. No.: US 2025/0344416 A1
(43) Pub. Date: Nov. 6, 2025

(54) 3D PRINTED ION TRAP

(71) Applicant: University of Oregon, Eugene, OR (US)

(72) Inventors: David Allcock, Eugene, OR (US); Timothy Gardner, Eugene, OR (US); Alexander Quinn, Eugene, OR (US); Morgan Brown, Eugene, OR (US)

(73) Assignee: University of Oregon, Eugene, OR (US)

(21) Appl. No.: 18/864,382

(22) PCT Filed: May 4, 2023
(86) PCT No.: PCT/US2023/020964

§ 371 Date: Nov. 8, 2024

Related U.S. Application Data
(60) Provisional application No. 63/340,339, filed on May 10, 2022.

(51) Int. Cl. H10D 1/66; B33Y 80/00; H10D 62/81

(52) U.S. Cl. CPC H10D 1/66; B33Y 80/00; H10D 62/81

(57) ABSTRACT

An apparatus includes a first wall and a second wall extending from a planar surface of a substrate to a wall height, and a plurality of electrodes disposed on the first wall and the second wall. The first wall and the second wall can be spaced apart from one another along a first axis on the planar surface. The plurality of electrodes can be configured to generate an electric field to trap an ion at a trapping position located between the first wall and the second wall. A vertical distance between the trapping position and the planar surface of the substrate can be smaller than the wall height.

### CROSS-REFERENCE TO RELATED APPLICATIONS

This application claims the benefit of U.S. Provisional Patent Application No. 63/340,339, filed May 10, 2022, which is incorporated herein by reference in its entirety.

### FIELD

The present disclosure pertains to ion traps, methods of making ion traps, and quantum computing.

### BACKGROUND

Unlike transistor-based computing systems which process information encoded in binary bits (e.g., 1s and 0s), quantum computing systems process information that is represented by quantum bit or qubit. Qubits can be encoded with particles (e.g., electrons) exhibiting quantum mechanical characteristics such as superposition and entanglement. For example, qubits can be defined by a superposition of two basic states (e.g., |0> and |1>), and a pair or group of particles can be entangled when the quantum state of each particle cannot be described independently of the quantum state of the other particles. Quantum computing can perform computations at a much faster rate than transistor-based computers, thus having the potential to revolutionize computation by making certain types of classically intractable problems solvable.

One promising mechanism to implement quantum computing is based on ion traps, where charged particles (e.g., atomic or molecular ions) can be trapped in a free-space position using dynamic electric fields. An example ion trap is the so-called Paul trap, which is a type of quadrupole ion trap that uses static direct current (DC) and oscillating radio frequency (RF) electric fields to trap ions. The trapped ions can be addressed and read-out optically using optical signals. For example, lasers can be applied to induce coupling between the qubit states (for single qubit operations) or coupling between the internal qubit states and the external motional states (for entanglement between qubits).

Although tremendous progress has been made in the past years to investigate various types of ion traps for quantum computing, challenges remain on designing ion traps that are easy to fabricate and have superior trap performance. Thus, there is room for improvement of ion trap design.

### SUMMARY

Certain examples of the disclosure concern an ion trap assembly disposed on a planar surface of a substrate. The ion trap assembly can include a first wall and a second wall extending vertically above the planar surface of the substrate to a wall height, and a plurality of electrodes disposed on the first wall and the second wall. The first wall and the second wall can be spaced apart from one another along a first axis on the planar surface. The plurality of electrodes can be configured to generate an electric field to trap an ion at a trapping position located between the first wall and the second wall. A vertical distance between the trapping position and the planar surface of the substrate can be smaller than the wall height.

Certain examples of the disclosure also concern an ion tramp assembly including a 3D structure disposed on a planar surface of a substrate and a plurality of electrodes coated on the 3D structure. The 3D structure can include an organically modified ceramic material.

Certain examples of the disclosure further concern a device including a substrate and an ion trap assembly disposed on the substrate. The ion trap assembly can be any one of the ion trap assemblies described above.

Certain examples of the disclosure also concerns a method including preparing a substrate, printing a 3D structure on the substrate, and selectively coating the 3D structure with a metal to form a plurality of electrodes. Printing the 3D structure can include printing a first wall and a second wall extending vertically above a planar surface of the substrate to a wall height. Selectively coating the 3D structure can include coating at least one electrode on the first wall and coating at least one electrode on the second wall.

The foregoing and other objects, features, and advantages of the disclosed technologies will become more apparent from the following detailed description, which proceeds with reference to the accompanying figures.

### BRIEF DESCRIPTION OF THE DRAWINGS

FIG. 1 is a block diagram depicting an example quantum computing system based on ion traps.

FIG. 2A is a cross-sectional view of an integrated structure having a surface electrode ion trap.

FIG. 2B is a cross-sectional view of an integrated structure having a trench geometry ion trap.

FIG. 3A depicts a cross-sectional view of a symmetric surface electrode ion trap, according to one example.

FIG. 3B depicts a cross-sectional view of a symmetric plain trench geometry ion trap, according to one example.

FIG. 3C depicts a cross-sectional view of a symmetric stacked trench geometry ion trap, according to one example.

FIG. 3D depicts a cross-sectional view of a symmetric 3D wafer ion trap, according to one example.

FIG. 4A depicts a cross-sectional view of an anti-symmetric surface electrode ion trap, according to one example.

FIG. 4B depicts a cross-sectional view of an anti-symmetric plain trench geometry ion trap, according to one example.

FIG. 4C depicts a cross-sectional view of an anti-symmetric stacked trench geometry ion trap, according to one example.

FIG. 4D depicts a cross-sectional view of an anti-symmetric 3D wafer ion trap, according to one example.

FIG. 5A is a schematic cross-sectional view of the potential generated by a surface electrode ion trap, according to one example.

FIG. 5B is a schematic cross-sectional view of the first three multipoles of the potential depicted in FIG. 5A, according to one example.

FIG. 5C is a schematic cross-sectional view of the pseudopotential associated with the potential depicted in FIG. 5A, according to one example.

FIGS. 6A-6D show certain simulation results comparing trapping performance of surface electrode ion traps, symmetric and anti-symmetric plain trench geometry ion traps, according to one example, and FIG. 6E is a figure legend depicting data shown in FIGS. 6A-6D.

FIGS. 7A-7D show additional simulation results comparing trapping performance of surface electrode ion traps, symmetric and anti-symmetric plain trench geometry ion traps, according to one example, and FIG. 7E is a figure legend depicting data shown in FIGS. 7A-7D.

FIGS. 8A-8D show certain simulation results comparing trapping performance of surface electrode ion traps, 3D wafer ion traps, and symmetric stacked trench geometry ion traps, according to one example, and FIG. 8E is a figure legend depicting data shown in FIGS. 8A-8D.

FIGS. 9A-9D show additional simulation results comparing trapping performance of surface electrode ion traps, 3D wafer ion traps, and symmetric stacked trench geometry ion traps, according to one example, and FIG. 9E is a figure legend depicting data shown in FIGS. 9A-9D.

FIGS. 10A-10D show certain simulation results comparing trapping performance of surface electrode ion traps, 3D wafer ion traps, and anti-symmetric stacked trench geometry ion traps, according to one example, and FIG. 10E is a figure legend depicting data shown in FIGS. 10A-10D.

FIGS. 11A-11D show additional simulation results comparing trapping performance of surface electrode ion traps, 3D wafer ion traps, and anti-symmetric stacked trench geometry ion traps, according to one example, and FIG. 11E is a figure legend depicting data shown in FIGS. 11A-11D.

FIG. 12 is a flowchart depicting an example method of fabricating an ion trap.

FIG. 13A is a schematic illustrating components of an exemplary raster-scanning direct laser writing (rDLW) printer.

FIG. 13B is a schematic depicting directions and dimensions in a build envelope of the rDLW printer of FIG. 13A.

FIG. 14A is an overhead view of a grid of symmetric stacked trench geometry ion traps, according to one example.

FIG. 14B is an oblique view of the grid of FIG. 14A.

FIG. 14C is a close-up view of an intersection of trenches depicted in FIGS. 14A-14B.

FIG. 14D is a close-up view of a DC electrode segment of one of the symmetric stacked trench geometry ion traps depicted in FIGS. 14A-14C.

FIG. 15 is a schematic showing an exemplary process of preparing a substrate in fabrication of a trench geometry ion trap.

FIG. 16 is a schematic showing an exemplary process of printing a 3D structure and selectively metalizing the 3D structure in fabrication of a trench geometry ion trap.

FIGS. 17A-17E schematically depict various steps fabricating a trench geometry ion trap, according to one example.

### DETAILED DESCRIPTION

### General Considerations

For purposes of this description, certain aspects, advantages, and novel features of the embodiments of this disclosure are described herein. The disclosed methods, apparatus, and systems should not be construed as being limiting in any way. Instead, the present disclosure is directed toward all novel and nonobvious features and aspects of the various disclosed examples, alone and in various combinations and sub-combinations with one another. The methods, apparatus, and systems are not limited to any specific aspect or feature or combination thereof, nor do the disclosed examples require that any one or more specific advantages be present or problems be solved. The technologies from any example can be combined with the technologies described in any one or more of the other examples. In view of the many possible examples to which the principles of the disclosed technology may be applied, it should be recognized that the illustrated examples are only preferred examples and should not be taken as limiting the scope of the disclosed technology.

Although the operations of some of the disclosed examples are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed methods can be used in conjunction with other methods. Additionally, the description sometimes uses terms like “provide” or “achieve” to describe the disclosed methods. These terms are high-level abstractions of the actual operations that are performed. The actual operations that correspond to these terms may vary depending on the particular implementation and are readily discernible by one of ordinary skill in the art.

As used in this application and in the claims, the singular forms “a,” “an,” and “the” include the plural forms unless the context clearly dictates otherwise. Additionally, the term “includes” means “comprises.” Further, the terms “coupled” and “connected” generally mean electrically, electromagnetically, and/or physically (e.g., mechanically or chemically) coupled or linked and does not exclude the presence of intermediate elements between the coupled or associated items absent specific contrary language.

Directions and other relative references (e.g., inner, outer, upper, lower, etc.) may be used to facilitate discussion of the drawings and principles herein, but are not intended to be limiting. For example, certain terms may be used such as “inside,” “outside,”, “top,” “down,” “interior,” “exterior,” and the like. Such terms are used, where applicable, to provide some clarity of description when dealing with relative relationships, particularly with respect to the illustrated examples. Such terms are not, however, intended to imply absolute relationships, positions, and/or orientations. For example, with respect to an object, an “upper” part can become a “lower” part simply by turning the object over. Nevertheless, it is still the same part and the object remains the same. As used herein, “and/or” means “and” or “or,” as well as “and” and “or.”

As used herein, the term “approximately” and “about” means the listed value and any value that is within 20% of the listed value. For example, “about 1” means any value between about 0.8 and about 1.2, inclusive.

### Overview of Ion Trap-Based Quantum Computing System

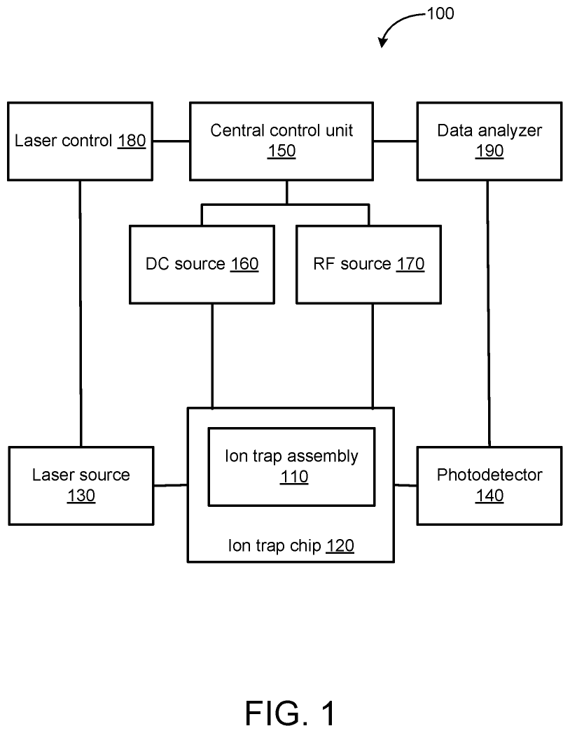

FIG. 1 is a block diagram depicting an example quantum computing system 100 based on ion traps.

The quantum computing system 100 includes at least one ion trap chip 120 which comprises one or more ion traps 110 (also referred to as “ion trap assemblies”). Examples of the ion traps 110, including trench geometry ion traps, are described further below. As noted above, each of the ion traps 110 can be configured to trap one or more charged particle in a free-space position using dynamic electric fields, and such trapped ion can be addressed and read-out optically.

In certain examples, the ion traps 110 can be configured to be quadrupole ion traps that uses an electric field having both DC and RF components to trap ions. For example, the ion trap chip 120 can be connected to a DC source 160 and an RF source 170, which respectively provide DC and RF voltages to the one or more ion traps 110. As described below, each ion trap 110 can have one or more DC electrodes and one or more RF electrodes. The DC source 160 can be connected to the one or more DC electrodes and configured to generate the DC component of the electric field, and the RF source 170 can be connected to the one or more RF electrodes and configured to generate the RF component of the electric field.

The DC source 160 and the RF source 170 can be connected to a central control unit 150, which can include one or more processors and associated memories and run a control software stored in the memories. The central control unit 150 can program various operational parameters of the DC source 160 and the RF source, such as the DC voltage and RF frequency. In certain examples, the DC voltage applied to the ion traps 110 can range from about 10 V to about 1000 V or higher, and the RF voltage applied to the ion traps can have a frequency ranging from about 10 MHz to about 100 MHz or higher. In certain examples, the DC voltage applied to different DC electrodes can be different. In certain examples, the DC voltage applied to a particular DC electrode can also vary at different time periods. In certain circumstances, the RF frequency applied to different RF electrodes can be fixed. The amplitude of the RF voltage (which can vary in time) applied to different RF electrodes at any selected timepoint can be the same or different.

The central control unit 150 can also configure and program a laser control unit 180, which is connected to at least one laser source 130. Under the control of the laser control unit 180, the laser source 130 can generate laser pulses, which can be guided through an optical path (e.g., lenses, optical waveguide, grating coupler, etc.) and shine on ions trapped in ion traps 110.

The quantum computing system 100 can further include one or more photodetectors 140 configured to read out the state of the qubits stored in the trapped ions. For example, the quantum computing system 100 can be configured so that one qubit state of a trapped ion does not interact with the laser pulses and the trapped ion remains dark, whereas another qubit state of the trapped ion absorbs the laser light and re-emits it (i.e., it fluoresces). The re-emitted fluorescence can be sufficiently bright, e.g., about 100 million photons per second, so that it can be detected by the photo detectors 140.

The optical signal acquired by the photodetector 140 can be sent to a data analyzer 190, which can be further programmed and controlled by the central control unit 150. In certain cases, the data analyzer 190 can be a software module implemented by the central control unit 150. By analyzing the signals generated by the photodetector 140, the qubits of the trapped ions can be analyzed and used for quantum computing.

Although not shown, it is to be understood that the quantum computing system 100 can also include other components, such as amplifiers and/or filters for the DC source 160 and the RF source 170, digital-to-analog converters (DAC) and/or analog-to-digital converters (ADC) respectively used for laser generation and optical signal acquisition, a vacuum pump configured to generate a vacuum environment enclosing the ion trap chip, etc.

### Overview of Surface-Electrode Ion Traps and 3D Wafer Ion Traps

Microfabricated ion traps in use for quantum computation can be generally categorized as one of two types: the two-dimensional (2D) surface-electrode ion trap (hereinafter “SET”) or the three-dimensional (3D) wafer-type ion trap (hereinafter “3D wafer ion trap”).

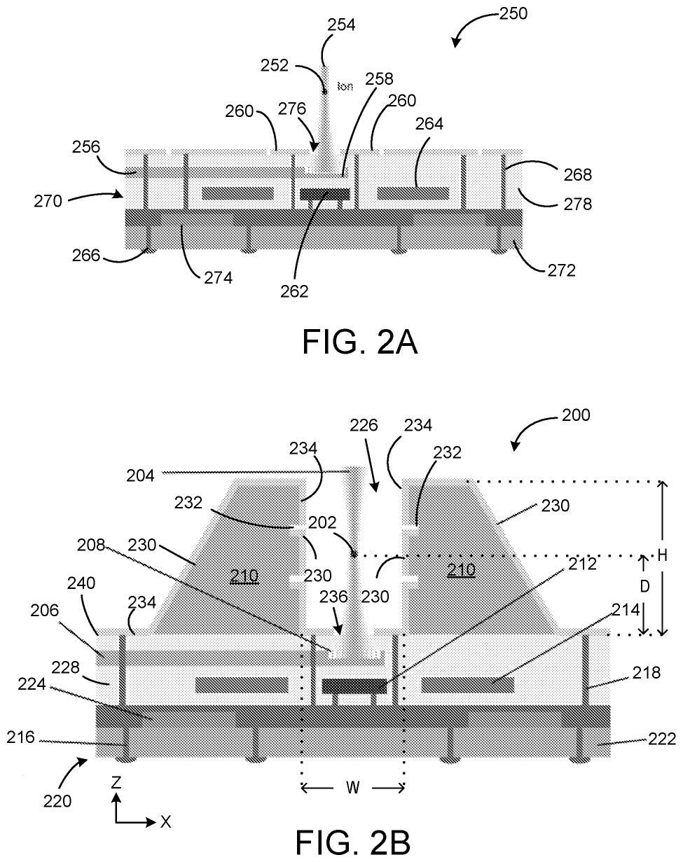

FIG. 2A schematically shows a cross-sectional view of an example SET 250 having an integrated structure. As shown, the SET 250 includes a plurality of trap electrodes 260 fabricated as a single layer on a substrate 270 comprising a wafer 272, which can be made of silicon, glass, aluminum nitride, sapphire, etc., or any combination thereof. When the SET 250 is operating, the ion(s), e.g., 252, can be trapped above the trap electrodes 260. For example, the trapped ions 252 can be within a few tens of micrometers to the top surface of the trap electrodes 260. The planar geometry of SET 250 has allowed for a diverse range of ion traps to be easily fabricated with rapid turnaround in relatively simple university cleanrooms as well is in commercial MEMS and CMOS processes.

For example, underneath the top layer of trap electrodes 260, there can be other functional layers containing many classical control elements, such as current-carrying wires (e.g., 264) for magnetic field-driven gates, photonic integrated circuits for laser delivery, superconducting nanowires, avalanche photodiodes (e.g., 262) for photon detection, active CMOS electronics (e.g., 274) such as DACs for trap voltage generation, routing layers (e.g., 278), electrical routing (e.g., 268), and thru-wafer vias (e.g., 266) to external connections. The integrated structure of the SET 250 can also include an optical waveguide 256 and a grating coupler 258 for guiding a laser light 254 generated from a laser source (e.g., 130) to pass through an aperture 276 between the trap electrodes 260. The light 254 can be received by the trapped ion(s) 252.

Practical SET fabrication processes can allow trapped-ion quantum computers to scale via standard semiconductor industry fabrication techniques. However, SET geometry constrains SETs to have much lower trapping efficiency, depth, and harmonicity compared to 3D wafer ion traps.

For example, the trapping potentials of SETs are less harmonic than 3D wafer ion traps. This lower harmonicity can produce an undesirable shift of trap frequencies from any slight displacement of the trapping location due to stray charges or control voltage inaccuracies. Without recalibration, this can lead to errors in multi-qubit gates. The increased cross-Kerr nonlinearity can also lead to gate errors due to spectator modes.

In addition, compared to 3D wafer ion traps, SETs have much lower trap depths, typically close to room temperature. This lower trap depth makes loading ions less efficient and ion losses much more likely, e.g., due to control field errors, stray charges, and background gas collisions. Room temperature operation of more than a couple of ions in lighter ion species can be effectively precluded due to short ion lifetimes. Junctions between ion traps with favorable trapping strength and depth, and small pseudopotential barriers can be harder to achieve than the 3D wafer ion traps.

In addition, as the ions are trapped in an open volume above a surface electrodes, they are poorly shielded from electric charges or crosstalk (photons, microwave control fields, or electric trapping fields) from other trapping zones on the SET.

3D wafer ion traps can be made by stacking a number of individual wafers on top of each other but with gaps between adjacent wafers. The wafers can be either made of conductive materials, or insulating materials that are subsequently coated in metal to create electrodes. The ions can be trapped at the gaps between the stacked wafers. 3D wafer ion traps offer superior trap performance, and can be operated at room temperature down to cryogenic temperatures of a few degrees Kelvin. However, the fabrication and assembly process for 3D wafer traps is fairly complex. For example, fabrication of 3D wafer traps can require thru-wafer machining, along with alignment and stacking of multiple wafers, to achieve desired geometries. These processes generally preclude CMOS-like monolithic approaches to integrating functional elements, and instead rely on further serial assembly of bespoke and heterogeneous components. Thus, fabrication of 3D wafer traps can be difficult to scale.

Disclosed examples described herein can overcome the shortcomings of both SETs and 3D wafer ion traps. As described more fully below, some disclosed ion trap examples include a trench geometry that can still allow planar electrode layer but with improved trapping properties. Further, many disclosed ion trap examples can be 3D-printed over a 2D wafer with microfabricated components already integrated into the 2D wafer. In this way, the integration techniques and scaling advantages of SETs can be retained. Representative examples demonstrate the first application of additive 3D printing technology to ion trap fabrication.

Overview of Example Integrated Ion Trap Assembly with a Trench Geometry

Various disclosed examples can use 3D printing to form 3D ion trap structures. 3D printing can provide improved geometric versatility in 3D trap configuration, e.g., by allowing arbitrary shapes to be produced. In some examples, electrodes can be 3D printed with hyperbolic cross-sections. Such electrodes can generate clean quadrupole potentials, producing lower anharmonicities (as discussed further below) than other geometries. Choices of trap geometry can be informed by other fabrication and operation constraints, e.g., whether the geometry allows optical access to the ion for laser beam delivery and fluorescence detection and how easily the 3D-printed dielectric can be metalized (a problem discussed further below). As described herein, example ion traps can include various trench geometries. In representative examples, trench geometries can be configured to mimic 3D trap electrodes having hyperbolic cross-sections while still allowing optical access to the ion for laser beam delivery and fluorescence detection.

As described herein, an ion trap with a trench geometry can refer to a 3D structure configured to confine an ion between at least two walls (also referred to as “trench walls”). As described below, trench walls can be 3D printed on a surface of a wafer. FIG. 2B schematically depicts a cross-sectional view of an ion trap 200 having an example trench geometry.

In the depicted example, the ion trap 200 has a 3D structure that can include two walls 210 extending vertically above a planar (top) surface 240 of a substrate 220. As shown, the substrate 220 can include a wafer layer 222, such as a silicon wafer layer. As described further below, the walls 210 can comprise a dielectric material such as organically modified ceramic. A space between the two walls 210 and above the planar surface 240 can define a trench 226 of the ion trap 200.

In certain examples, the two walls 210 can have about the same wall height H measured along a Z-axis from the planar surface 240 to the top of the walls 210. The two walls 210 can be spaced apart from one another along a first axis (e.g., X-axis) on the planar surface 240. The X-axis is perpendicular to the Z-axis and the walls 210. As shown, the two walls 210 can have respective inner surfaces 234 that are substantially perpendicular to the planar surface 240. The distance between the two walls 210, measured along the X-axis and between the two inner surfaces 234, can define a trap width W (also referred to as “trench width”).

A plurality of electrodes 230 can be disposed on each of the two walls 210. The plurality of electrodes 230 can include one or more DC electrodes and one or more RF electrodes. In certain examples, some of the plurality of electrodes 230 can be segmented or isolated from one another, e.g., by gaps or cuts 232 on the walls 210. As shown in FIG. 2B, at least some of the electrodes 230 can extend onto a floor of the trench 226 (e.g., the planar surface 240 between the two walls 210).

When operating, the plurality of electrodes 230 can generate an electric field to trap an ion 202 at a trapping position located between the two walls 210 (i.e., within the trench 226). Thus, the space occupied by the trench 226 may also be referred to as an ion trap volume. In representative examples, a vertical distance (D) between the trapping position of the ion 202 and the planar surface 240 of the substrate 220 is smaller than the wall height H. For example, the vertical distance D can be about half of the wall height H.

The trapping position of the ion 202 can be located on a trapping axis, which extends into and out of the page in FIG. 2B (i.e., the trapping axis is perpendicular to the cross-section depicted in FIG. 2B). Generally, the trapping axis (and thus the trapping position) is located halfway between the two walls 210.

In certain examples, the vertical distance D from the trapping position to the planar surface 240 can be about the same as or larger than the distance between the trapping position and any of the walls 210 measured along the first axis. Thus, when the trapping position is located midway between the two walls 210, the vertical distance D can be about the same as or larger than half of the trap width, i.e., W/2. In one particular example, the vertical distance D from the trapping position to the planar surface 240 can be approximately the same as the trap width W.

In certain examples, the trap width is between 25 μm and 1 mm, inclusive. In one particular example, the trap width is between 50 μm and 150 μm, inclusive.

In certain examples, the wall height His at least 50% of the trap width W. In certain examples, the wall height H is about the same as the trap width W. In certain examples, the wall height H can be larger than the trap width W.

In certain examples, the wall height H is greater than 25 μm. For example, the wall height H can be between 50 μm and 1 mm, inclusive. As a more specific example, the wall height H can be between 200 μm 600 μm, inclusive.

In certain examples, each wall 210 can have a wall width (measured along the X-axis) ranging between 50 μm and 1 mm, inclusive.

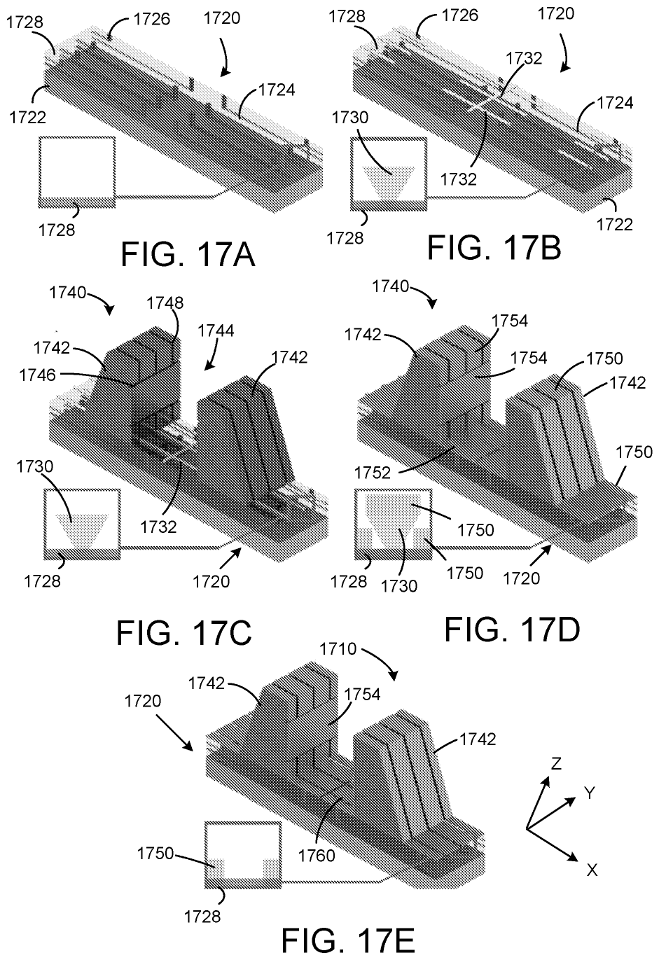

The two walls 210 can extend parallel along a second axis (e.g., Y-axis in FIG. 17E) that is perpendicular to the first axis (e.g., X-axis) on the planar surface 240. The Y-axis extends parallel to the trapping axis on which the trapping location of the ion 202 is located (i.e., the Y-axis in FIG. 2B extends into and out of the page). In many examples, the length (L) of each wall 210 measured along the second axis is larger than the trap width W. For example, the length (L) of each wall 210 measured along the second axis can be at least five times the trap width W. Larger length to width ratios can be configured to reduce a boundary effect of the electric field generated by the plurality of electrodes 230. In addition, a larger length L can allow multiple trap zones where ions can be transported between.

Similar to the SET 250 described above, the ion trap 200 can be integrated with many other control elements, such as current-carrying wires (e.g., 214) for magnetic field-driven gates, photonic integrated circuits for laser delivery, superconducting nanowires, photodiodes (e.g., 212) for photon detection, active CMOS electronics (e.g., 224) such as DACs for trap voltage generation, and routing layers (e.g., 228), electrical routing (e.g., 218) and thru-wafer vias (e.g., 216) to external connections. As described further below, at least some of the plurality of electrodes 230 can be connected to corresponding metal traces 234. The metal traces 234 can be created based on photopatterned electrical traces on the substrate 220. The integrated structure of the ion trap 200 can also include an optical waveguide 206 and a grating coupler 208 connected to a terminal end of the optical waveguide 206. The grating coupler 208 can be configured to redirect a laser light 204 generated from a laser source (e.g., 130) and travelling through the optical waveguide 206 to pass through an aperture 236 at a floor of the trench 226 (and between the two walls 210). The laser light 204 can pass into the trench 226, and can be received by the trapped ion 202.

As described herein, a 3D structure of an ion trap (e.g., 200) can refer to a structure that has a raised profile (e.g., via 3D printing of many stacked layers) above a substrate (e.g., 220) with a height-to-width ratio that is greater than 0.5 (e.g., 1:1, etc.). Example 3D structures are typically larger than electrical components formed via photolithography (or thin film) fabrication alone (e.g., without 3D printing the 3D structure onto a substrate).

3D structure examples of an ion trap can have a footprint on a substrate. For example, a footprint can refer to a 2D surface area that a 3D structure occupies on the substrate. A footprint of a 3D structure can define a width, which refers to the smallest dimension (or size) of the footprint extending through a geometric center of the footprint. For example, when the footprint has a circular shape, the width of the footprint is equal to a diameter of the circle. In the example depicted in FIG. 2B, the footprint of the ion trap 200 has a generally rectangular shape with a first dimension (e.g., width) W measured along the X-axis and a second dimension (e.g., length) L measured along the Y-axis. Since L is generally larger than W, the width of the footprint of the ion trap 200 is defined by the trap width W. Thus, for the ion trap 200, the height-to-width ratio can be calculated as H/W.

More generally, the height-to-width ratio of a 3D structure described herein can be defined as a ratio of the height (e.g., along the Z-axis) of the 3D structure to a width or diameter of the 3D structure (e.g., along an X or Y-axis), where a base or substrate from which the 3D structure extends is defined in the X-Y plane.

As described more fully below, the ion trap 200 can be fabricated by creating a 3D-printed dielectric structure (e.g., the walls 210) on top of the substrate 220 before coating the 3D structure with a metal to form the plurality of electrodes 230. This sequence can allow retaining fabrication advantages of an SET while also retaining the advantageous trapping geometry of a 3D wafer ion trap.

### Example Plain Trench Ion Trap Geometries

According to certain examples, an ion trap can have a plain trench geometry where each trench wall comprises only one electrode, which can be a DC electrode (connected to a DC source, e.g., 160) or an RF electrode (connected to an RF source, e.g., 170).

In certain examples, the plain trench geometry of an ion trap can be configured to be symmetric, meaning that the DC and/or RF electrodes within the ion trap are mirrored around a vertical plane (e.g., the plane is perpendicular to the substrate) along the trapping axis (e.g., the axis extending through the ion's trapping position). In other examples, the plain trench geometry of an ion trap can be configured to be anti-symmetric, meaning that the role of RF and DC electrodes is switched in mirroring halves of the ion trap around the vertical plane along the trapping axis.

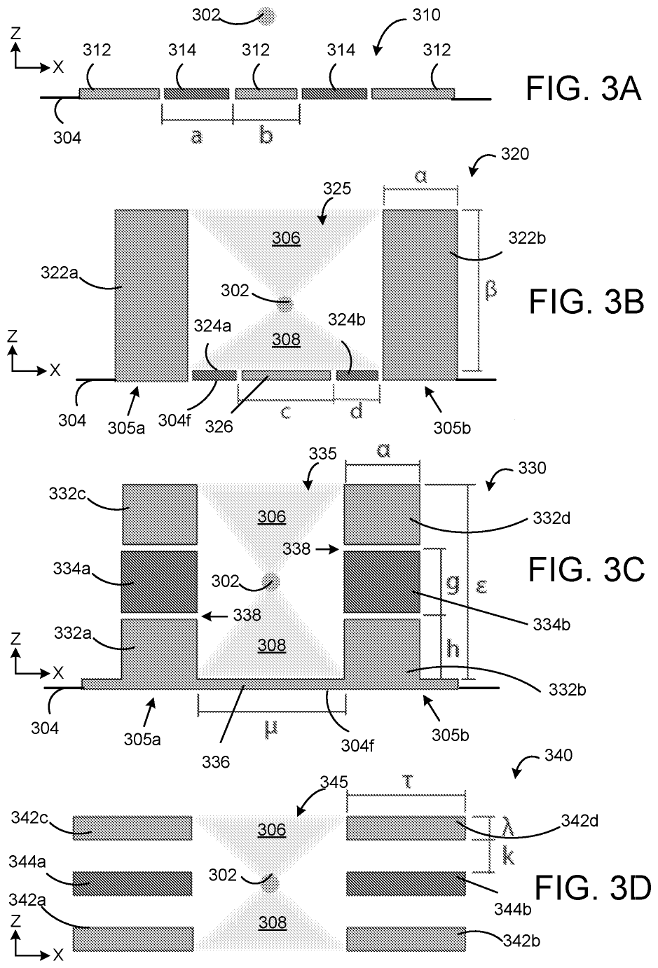

As an example, FIG. 3B shows a cross-sectional view (in X-Z plane) of an ion trap 320 with a symmetric plain trench geometry. As shown, two walls 305a, 305b extend vertically above a planar surface 304 of a substrate to define a trench 325. The walls 305a, 305b can have respective heights that are the same. Two electrodes 322a, 322b are disposed on the two walls 305a, 305b, respectively. For example, the electrodes 322a, 322b can be coated on selected outer surfaces of the two walls 305a, 305b. The electrodes 322a, 322b can also be referred to as base electrodes.

In the depicted example, both electrodes 322a, 322b extend vertically through the entire heights of the respective walls 305a, 305b. In other examples, the electrodes 322a, 322b may not extend all the way to the top of the respective walls 305a, 305b. For example, the electrodes 322a, 322b may extend vertically through a predefined height that is less than the wall height (e.g., 85%, 90%, 95% of the wall height, etc.). In some cases, the walls 305a, 305b may have different wall heights but the electrodes 322a, 322b on the walls can extend vertically to the same height from the planar surface 304.

As depicted in FIG. 3B, the planar surface 304 of the substrate can define a floor 304f (also referred to as “trench floor”) extending between the two walls 305a, 305b. One or more electrodes (e.g., 324a, 324b, 326) can be disposed on the floor 304f and between the two walls 305a, 305b, and such electrodes can also be referred to as floor electrodes.

In FIG. 3B, three floor electrodes (324a, 324b, and 326) are shown, each of which can be spaced apart and electrically isolated from the electrodes 322a, 322b respectively disposed on the walls 305a, 305b, e.g., via gaps between the electrodes.

In the depicted example, the floor electrodes include a center electrode, such as the electrode 326, located at a mid-portion between the two walls 305a, 305b, a flank electrode, such as the electrode 324a, located between the center electrode 326 and the base electrode 322a, and another flank electrode, such as the electrode 324b, located between the center electrode 326 and the base electrode 322b. The two flank electrodes 324a, 324b can have about the same electrode width measured along the X-axis.

When operating, the plurality of electrodes 322a, 322b, 324a, 324b, 326 can generate an electric field to trap an ion 302 at a trapping position located between the walls 305a, 305b. As described above, a vertical distance between the trapping position of the ion 302 and the planar surface 304 of the substrate is smaller than (e.g., about half of) the wall height (denoted as β in FIG. 3B).

The trapping position of the ion 302 can define two fields of view 306, 308 above and below the trapping position, respectively, based on which an upper and a lower open numerical aperture (NAs) available for fluorescence collection and for laser beam access can be calculated. For example, a laser beam can be directed to the ion 302 through the open space above the trench 325 and/or through gaps between the floor electrodes 324a, 324b, 326 which expose at least a portion of the substrate. Similarly, fluorescence emitted from the ion 302 can also be detected by photosensors located above the trench 325 and/or through gaps between the floor electrodes 324a, 324b, 326.

In the depicted example, base electrodes 322a, 322b and the center electrode 326 are DC electrodes, whereas flank electrodes 324a, 324b are RF electrodes. Alternatively, base electrodes 322a, 322b and the center electrode 326 can be RF electrodes, whereas flank electrodes 324a, 324b can be DC electrodes. In either case, the DC electrodes are configured to be symmetric about the trapping position along the X-axis, and the RF electrodes are also configured to be symmetric about the trapping position along the X-axis.

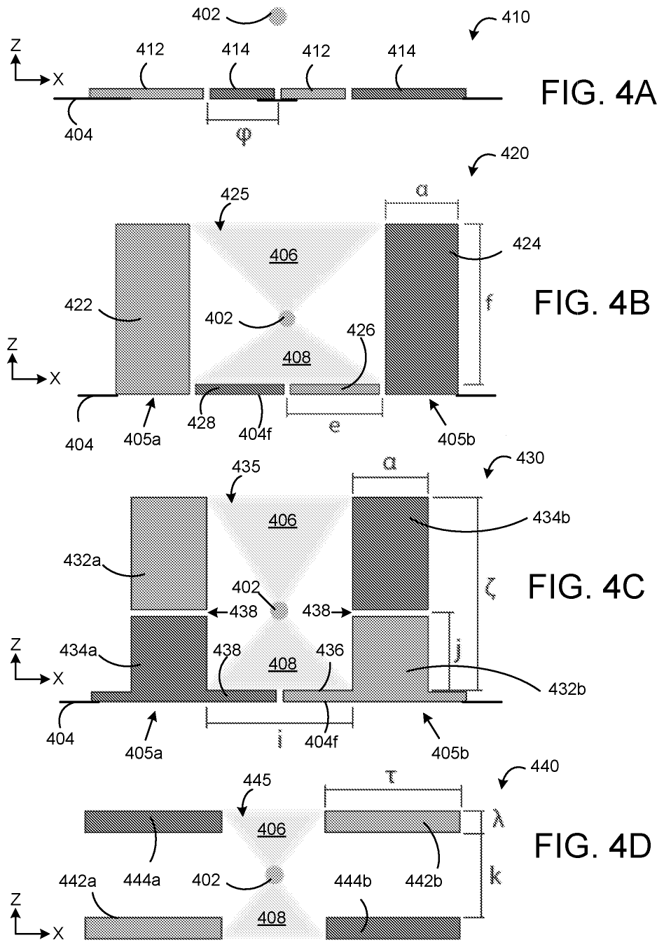

As another example, FIG. 4B shows a cross-sectional view (in X-Z plane) of an ion trap 420 with an anti-symmetric plain trench geometry. Two walls 405a, 405b extend vertically above a planar surface 404 of a substrate to define a trench 425. Two electrodes 422, 424 (or base electrodes) are respectively disposed on the two walls 405a, 405b. For example, the electrodes 422, 424 can be coated on selected outer surfaces of the two walls 405a, 405b. In the depicted example, both electrodes 422, 424 extend vertically through entire heights of the respective walls 405a, 405b. In other examples, the electrodes 422, 424 may not extend all the way to the top of the respective walls 405a, 405b.

The planar surface 404 of the substrate can define a trench floor 404f extending between the two walls 405a, 405b. One or more floor electrodes (e.g., 426, 428) can be disposed on the floor 404f, and each floor electrode can be spaced apart and electrically isolated from the electrodes 422, 424 respectively disposed on the walls 405a, 405b, e.g., via gaps between the electrodes.

In the depicted example, the floor electrodes include a side electrode 428 that is closer to the base electrode 422 than the base electrode 424 and another side electrode 426 that is closer to the base electrode 424 than the first base electrode 422. The two side electrodes 426, 428 can have about the same electrode width measured along the X-axis.

When operating, the plurality of electrodes 422, 424, 426, 428 can generate an electric field to trap an ion 402 at a trapping position located between the walls 405a, 405b and at a height that is smaller than (e.g., about half of) the wall height (denoted as f in FIG. 4B). The trapping position of the ion 402 can define two fields of view 406, 408 above and below the trapping position, respectively, based on which an upper and a lower open NAs available for fluorescence collection and for laser beam access can be calculated.

In the depicted example, one base electrode 422 is a DC electrode whereas the base electrode 424 is an RF electrode. Also, one side electrode 426 is a DC electrode whereas the side electrode 428 is an RF electrode. In contrast to the symmetric plain trench geometry depicted in FIG. 3B, FIG. 4B shows an anti-symmetric plain trench geometry. For example, the DC electrodes (e.g., 422, 426) are asymmetric about the trapping position along the X-axis, and the RF electrodes (e.g., 424, 428) are also asymmetric about the trapping position along the X-axis. Specifically, the DC electrodes (422, 426) and the corresponding RF electrodes (424, 428) are configured to be in mirror positions about the ion's trapping position.

It should be noted that, while FIGS. 3B and 4B show the cross-sectional view of respective ion traps with plain trench geometries, the electrodes coated on the trench walls (e.g., 305a, 305b, 405a, 405b) can also extend along a Y-axis that is perpendicular to the X-Z plane. In certain examples, a trench wall can include a plurality of segmented portions along the Y-axis. A plurality of electrodes (e.g., DC electrodes supplied by the same or different DC voltages) that are electrically insulated from each other can be disposed on respective segmented portions.

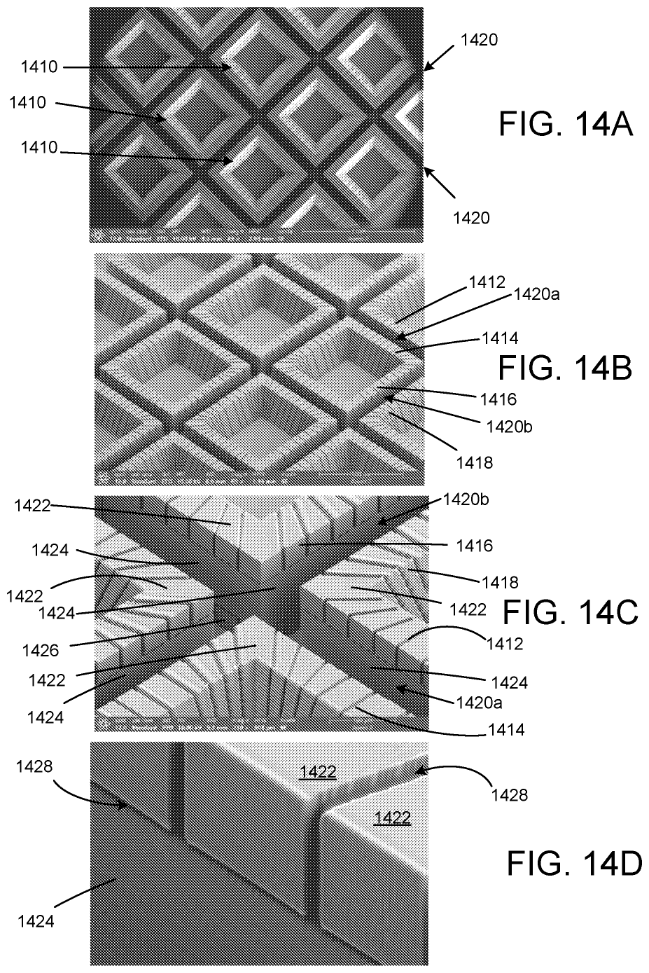

Examples of segmented trench walls with electrically isolated DC electrodes along the Y-axis are depicted in FIGS. 14A-14D and 17C-17E. Although the examples depicted in FIGS. 14A-14D and 17C-17E have a stacked trench geometry (as described further below), a plain trench geometry also can be used. In that case, the plain trench geometry is not limited to each wall having only one electrode. Instead, each wall can have a plurality of segmented electrodes arranged in a single layer and extending along the Y-axis.

The segmented DC electrodes along the Y-axis can provide axial confinement (along the trapping axis) of the ion using voltages applied to them. Generally, the RF electrodes can be connected to a common RF voltage source. The DC electrodes can be connected to multiple independent DC voltage sources for stationary trapping or dynamic trapping. For example, for stationary trapping, the voltages applied to these DC electrodes would be static (i.e., do not change over time). But by applying selected time-varying voltages to these DC electrodes, the trapped ions can also be moved along the trapping axis, and multiple ion crystals can be split, joined, and/or rotated.

Depending on the ion trap configuration, the number of DC and RF electrodes can vary. For example, the number of DC electrodes can more than the number of RF electrodes.

The DC and RF electrodes shown in FIGS. 3B and 4B can be configured to create a quadrupole trap, using two RF electrodes. It is to be understood that ion traps with a plain trench geometry (symmetric or anti-symmetric) can also be created with more electrodes than the examples shown in FIGS. 3B and 4B (e.g., by placing more floor electrodes on the trench floor), which can create higher pole ion traps.

### Example Stacked Trench Ion Trap Geometries

Examples of the plain trench geometry described above can provide arrangements that are closer to an ideal quadrupole geometry than a SET, but the flexibility of the single trench geometry can be limited by the fact that each trench wall is coated with only one layer of electrode (in the Z-axis).

According to certain examples, an ion trap can have a stacked trench geometry where each trench wall includes multiple DC and/or RF electrodes, e.g., with a coating of multiple layers along the Z-axis. By allowing multiple electrodes to be disposed on the trench walls, arrangements can be provided that more closely match the boundary conditions of a quadrupole, despite the fact that the trench remains open on the top.

Similar to plain trench geometries, stacked trench geometries of an ion trap can be configured to be symmetric, e.g., the DC and/or RF electrodes within the ion trap are mirrored around a vertical plane (e.g., the plane is perpendicular to the substrate) along the trapping axis (e.g., the axis extending through the ion's trapping position). In other examples, stacked trench geometries of ion traps can be configured to be anti-symmetric, i.e., that the role of RF and DC electrodes is switched in mirroring halves of the ion trap around the vertical plane along the trapping axis.

As an example, FIG. 3C shows a cross-sectional view (in X-Z plane) of an ion trap 330 with a symmetric stacked trench geometry. As shown, two walls 305a, 305b extend vertically above a planar surface 304 of a substrate to define a trench 335. Three stacked electrodes 332a, 334a, and 332c are disposed or coated on selected outer surfaces of the wall 305a, and three other stacked electrodes 332b, 334b, and 332d are disposed or coated on selected outer surfaces of the wall 305b. On both walls 305a, 305b, the two top electrodes 332c, 332d are electrically isolated from the respective two middle electrodes 334a, 334b, which are also electrically isolated from the respective two bottom electrodes 332a, 332b. The two bottom electrodes 332a, 332b can also be referred to as base electrodes.

To create isolation between stacked electrodes in each wall, cuts 338 can be created on the inner surface of each wall between the stacked electrodes. The cuts 338 can extend parallel to the planar surface 304 of the substrate. In some examples, the cuts 338 can have a convoluted shape (e.g., sinusoidal, zigzag, etc.) which can help reduce likelihood of shorting between electrodes caused by metal deposition. In certain examples, the depth of the cuts 338 measured along the X-axis can range from 1 μm to 100 μm, inclusive. In certain examples, the width of the cuts 338 measured along the Z-axis can range from 1 μm to 10 μm, inclusive.

In certain examples, the top electrodes 332c, 332d can be aligned with the top edge of the respective wall 305a, 305b. In other examples, the top electrodes 332c, 332d may have an offset from the top edge of the respective walls 305a, 305b.

Similar to the plain trench geometry, the planar surface 304 of the substrate can define a trench floor 304f extending between the two walls 305a, 305b. In addition, a floor electrode 336 can be disposed on the trench floor 304f.

In certain examples, the two top electrodes 332c, 332d can have about the same height as the bottom electrodes 332a, 332b. In other examples, the two top electrodes 332c, 332d can have different height than the bottom electrodes 332a, 332b.

In certain examples, the two middle electrodes 334a, 334b can have about the same height as the bottom electrodes 332a, 332b. In other examples, the two middle electrodes 334a, 334b can have a larger or smaller height than the bottom electrodes 332a, 332b.

When operating, the plurality of electrodes in the ion trap 330 can generate an electric field to trap an ion 302 at a trapping position located between the walls 305a, 305b and at a height that corresponds to about the mid-level of the middle electrodes 334a, 334b.

In some examples, the two top electrodes 332c, 332d and the unitary base electrode (formed by 332a, 332b, and 336) are DC electrodes, whereas the two middle electrodes 334a, 334b are RF electrodes. Both the DC electrodes and RF electrodes are configured to be symmetric about the trapping position along the X-axis.

In other examples, the two top electrodes 332c, 332d, the two bottom electrodes 332a, 332b, and the floor electrode 336 can be RF electrodes, whereas the two middle electrodes 334a, 334b can be DC electrodes. In such configuration, the floor electrode 336 can be connected to (or integrated with) both bottom electrodes 332a, 332b so as to define a unitary base electrode extending from the wall 305a to the wall 305b. Similarly, both the DC electrodes and RF electrodes are configured to be symmetric about the trapping position along the X-axis.

Similarly, the trapping position can define two fields of view 306, 308 above and below the trapping position, respectively, based on which an upper and a lower open NAs available for fluorescence collection and for laser beam access can be calculated. Note that although the cross-section of the ion trap 330 in FIG. 3C depicts a unitary base electrode extending between the two walls 305a, 305b, gaps can still be formed on the trench floor 304f, e.g., at different cross-sections along the Y-axis (see, e.g., the gap 1760 extending in X-axis at FIG. 17E), to expose at least a portion of the substrate for laser beam access and/or fluorescence collection.

As another example, FIG. 4C shows a cross-sectional view (in X-Z plane) of an ion trap 430 with an anti-symmetric stacked trench geometry. Similarly, two walls 405a, 405b extend vertically above a planar surface 404 of a substrate to define a trench 435. As shown, an upper electrode 432a is stacked on top of, and electrically isolated from (e.g., via a cut 438), one base electrode 434a on the wall 405a. Another upper electrode 434b is stacked on top of, and electrically isolated from (e.g., via a cut 438), one base electrode 432b on the wall 405b.

In certain examples, the upper electrodes 432a, 434b can be aligned with the top edge of the respective wall 405a, 405b. In other examples, the upper electrodes 432a, 434b may have an offset from the top edge of the respective walls 405a, 405b.

Similarly, the planar surface 404 of the substrate can define a trench floor 404f extending between the two walls 405a, 405b. As shown, two floor electrodes 436, 438 can be disposed on the trench floor 404f and have about the same width measured along the X-axis. The two floor electrodes 436, 438 can be separated and electrically isolated from one another, e.g., by a gap therebetween.

As shown, one floor electrode 436 can be connected to or integrated with the base electrode 432b, and the other floor electrode 438 can be connected to or integrated with the base electrode 434a. Thus, the floor electrode 436 can be deemed as a planar portion of the base electrode 432b extending from the wall 405b toward the wall 405a, and the floor electrode 438 can be deemed as a planar portion of the base electrode 4324a extending from the wall 405a toward the wall 405b.

In certain examples, the two upper electrodes 432a, 434b can have about the same height as the base electrodes 434a, 432b. In other examples, the two upper electrodes 432a, 434b can have a larger or smaller height than the base electrodes 434a, 432b. In certain examples, the height of the base electrodes 434a, 432b can range between 50 μm and 500 μm, or between 75 μm and 280 μm, inclusive.

When operating, the plurality of electrodes in the ion trap 430 can generate an electric field to trap an ion 402 at a trapping position located between the walls 405a, 405b. The height of the trapping position can approximately align with the gaps 438 when the heights of the upper electrodes 432a, 434b and the base electrodes 434a, 432b are relatively large. If either the height of the upper electrodes 432a, 434b or the height of the base electrodes 434a, 432b is relatively small, the height of the trapping position may deviate from the height of the gaps 438.

In the depicted example, one upper electrode 432a and one base electrode 432b (including the connected floor electrode 436) located on opposing walls are DC electrodes. The other upper electrode 434b and the other base electrode 434a (including the connected floor electrode 438) located on opposing walls are RF electrodes. In other examples, the arrangement of the DC and RF electrodes can be switched. In either case, the DC electrodes and the corresponding RF electrodes are configured to be in mirror positions about the ion's trapping position.

Similarly, the trapping position can define two fields of view 406, 408 above and below the trapping position, respectively, based on which an upper and a lower open NAs available for fluorescence collection and for laser beam access can be calculated.

Note that FIGS. 3C and 4C only show the cross-sectional view of respective ion traps with stacked trench geometries. The electrodes coated on the trench walls can also extend along a Y-axis that is perpendicular to the X-Z plane. In certain examples, as depicted in FIGS. 14A-14D and 17C-17E, a trench wall can include a plurality of segmented portions along the Y-axis, and a plurality of electrodes (e.g., DC electrodes) that are electrically insulated from each other can be disposed on respective segmented portions. The segmented DC electrodes along the Y-axis can provide axial confinement (along the trapping axis) of the ion by applying independent voltages to those electrodes. In certain examples, the RF electrodes can be connected to a common RF voltage source. The DC electrodes can be connected to multiple independent DC voltage sources for stationary trapping or dynamic trapping, as described above.

Although specific anti-symmetric trench geometries are shown in FIGS. 3C and 4C, it should be understood that many asymmetric variations on these ion traps are possible based on the same principles described herein. For example, although each of the ion traps 330, 430 has two RF electrodes so as to create a quadrupole trap, additional electrodes can be added to create higher pole ion traps. In one example, adding an extra layer of RF electrodes to the symmetric stacked trench ion trap 330 (e.g., two RF electrodes are each trench wall) would create a predominantly octuple trap. In another example, adding an extra layer of RF electrodes in the anti-symmetric stacked trench ion trap 430 (e.g., two RF electrodes on one trench wall and one RF electrode on the other trench wall) would create a predominantly hexapole trap.

### Simulation Overview and Parameters of Quantifying Trap Performance

Trapping performance of ion traps with different geometries can be compared through computer simulation studies.

For example, in one computer simulation study, different designs of ion trap were simulated using COMSOL Multiphysics using the boundary element method (BEM). The Electrode software package was used for further post-processing of the electric fields extracted from the simulations.

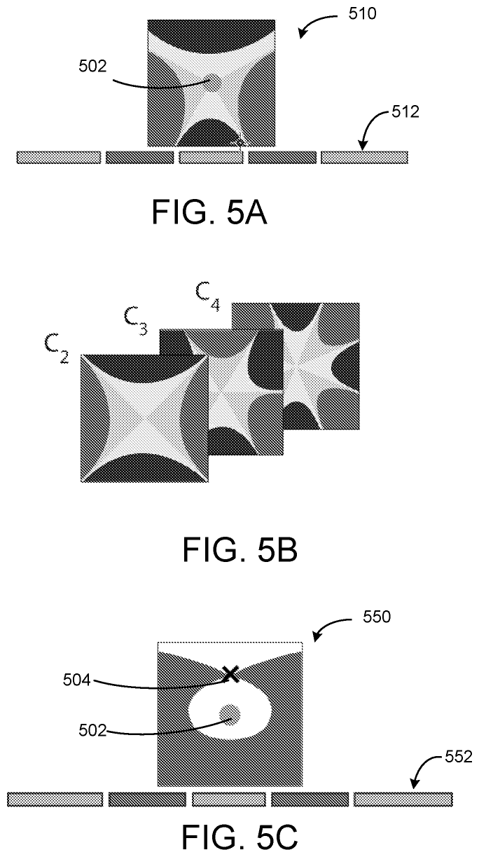

In each ion trap simulation, the electric field generated in the vicinity of the ion can be calculated by setting the RF electrodes to unit voltage and grounding all DC electrodes in the ion trap. Segmentation of the DC electrodes (see, e.g., FIGS. 14A-14D and 17C-17E) was not considered because it minimally affects simulation of the RF trapping pseudopotential. From the calculated electric fields, the pseudopotential of the ion trap, which is the effective potential seen by the ion, can be calculated. By finding where this pseudopotential is at a minimum in the plane perpendicular to the trapping axis, an equilibrium position of the ion in two dimensions can be located. For illustration, FIG. 5A shows a schematic cross-section of the potential 510 generated by a SET, with the equilibrium position of the ion marked with a dot 502. Different levels of potential are indicated by a gray scale 512.

By also finding the saddle point of the pseudopotential (also known as the “escape point”) and comparing the pseudopotential at this point to the pseudopotential at the center of the ion trap, a rough proxy for the depth of the ion trap can be determined. FIG. 5C shows a schematic cross-section of the pseudopotential 550 associated with the potential 510 shown in FIG. 5A, depicting the escape point (marked with a cross 504), the regions with a higher (grey) and lower (white) effective potential than the escape point, and the equilibrium position of the ion (marked with a dot 502). Different levels of pseudopotential are indicated by a gray scale 552.

At the ion's trapping position, it is feasible to fit the surrounding electric potential V=V(r, θ) to a cylindrical harmonic expansion by the following formula:

$$V ( r , θ ) = {V}_{0} {\sum }_{n = 2}^{∞} {{C}_{n} ( \frac{r}{{r}_{0}} )}^{n} cos ( n θ + {∅}_{n} ) + {V}_{off}$$

Here, r is distance from the center of the trapping position, r₀ is the minimum ion-electrode separation, V_{off} is the potential at the ion, Øₙ is the orientation of the nth-order multipole, and Cₙ is the expansion coefficient associated with an nth-order multipole. From these expansion coefficients, the quadrupole, hexapole, and octupole strengths generated by the ion traps can be defined as the following:

### Quadrupole, C₂

$$Hexapole , {C}_{3}^{′} = {C}_{3} / {C}_{2} \\ Octupole , {C}_{4}^{′} = {C}_{4} / {C}_{2}$$

For illustration, FIG. 5B shows schematic cross-sections of the first three multiples (C₂, C₃, and C₄) of the potential depicted in FIG. 5A, based on which the quadrupole, hexapole, and octupole can be determined.

The quadrupole term gives the geometric efficiency of an ion trap. Greater efficiency is desirable as it reduces the required RF voltage, and thus power dissipation as well as the possibility of voltage breakdown on the chip. The hexapole and octupole terms give the leading order anharmonicities in the potential and are normalized to the quadrupole term as it is most useful to compare ion traps at the same ion secular frequency, not the same RF voltage. Anharmonicities can introduce displacement-dependent frequency shifts in the ion's motion, increasing sensitivity of gate fidelity to the presence of stray electric fields. Thus, ion traps with smaller hexapole and octupole terms can be more desirable. This simulation only considers these leading-order anharmonicities because, for ion displacements r much smaller than ion-electrode separation r₀, the contribution of the nth term is of r/r₀ weaker than that of the (n−1)th term, for Cₙ˜Cₙ₋₁.

In addition to trap depth and the multipole components of the trapping potential, the open numerical aperture (NA) available for fluorescence collection and for laser beam access can also be calculated, as described above with reference to FIGS. 3B-3C and 4B-4C. A high NA (e.g., ˜0.4) is important for fast state readout on the ion. For the ion trap with trench geometries, the NA can be calculated both from above and from the substrate, as the ion detectors could be located in the substrate or placed above the trench. For the SETs, calculation of NA is unnecessary because the trapped ion is located at an open space above the electrodes. For the 3D wafer ion traps, due to their typical symmetry of stacked wafer layers, the NA is generally the same when it is calculated from both above and below the trapped ions. In this simulation, a circular detector is assumed, although a rectangular detector can also be used. The calculated NA can indicate the range of angles available for laser beams perpendicular to the trapping axis such that they can exit the trap without striking an electrode.

In this simulation, the ion traps are scaled such that the closest electrode to the ion is 75 μm away. Because anomalous heating has a strong ˜d⁴ dependence, the closest electrode will tend to dominate the heating rate. For calculating trap depths, it is assumed that a ⁴⁰Ca⁺ ion trapped at a secular frequency of 4 MHz by a 40 MHz RF trap drive with no DC potentials applied.

### Simulated SETs and 3D Wafer Ion Traps

For comparison purposes, the performance of ion traps with symmetric and anti-symmetric trench geometries can be compared with SETs and 3D wafer ion traps, which can also be configured to be symmetric or anti-symmetric.

As an example, FIG. 3A shows a cross-sectional view (in X-Z plane) of a SET 310 with a symmetric electrode configuration. As shown, the SET 310 includes three DC electrodes 312 and two RF electrodes 314 disposed on a planar surface 304 of a substrate, thus the SET 310 can also be referred to as a five-wire SET. An ion 302 can be trapped at a trapping position located at an open space above the electrodes 312, 314. Both the DC electrodes 312 and the RF electrodes 314 are symmetric about the trapping position along the X-axis.

FIG. 4A shows a cross-sectional view (in X-Z plane) of a SET 410 with an anti-symmetric electrode configuration. In this example, the SET 410 includes two DC electrodes 412 and two RF electrodes 414 disposed on a planar surface 404 of a substrate, thus the SET 410 can also be referred to as a four-wire SET. Similarly, an ion 402 can be trapped at a trapping position located above the electrodes 412, 414. The DC electrodes 412 and the RF electrodes 414 are configured to be in mirror positions about the ion's trapping position.

As another example, FIG. 3D shows a cross-sectional view (in X-Z plane) of a 3D wafer ion trap 340 with a symmetric electrode configuration. As shown, an ion 302 can be trapped in a space between two stacks of electrodes. One stack of electrodes include an RF electrode 344a stacked between two DC electrodes 342a, 342c. Another stack of electrodes include another RF electrode 344b stacked between two other DC electrodes 342b, 342d. The electrodes in the 3D wafer ion trap 340 can be coated on respective wafer layers which can be stacked together to form a multi-layer structure. Assuming equal distance between the layered wafers, the ion's trapping position can define an upper field of view 306 and a lower field of view 308, both of which have the same open NA. As shown, both the DC electrodes and the RF electrodes are symmetric about the trapping position along the X-axis.

FIG. 4D shows a cross-sectional view (in X-Z plane) of a 3D wafer ion trap 440 with an anti-symmetric electrode configuration. Similarly, an ion 402 can be trapped in a space between two stacks of electrodes. One stack of electrodes include an RF electrode 444a placed above a DC electrode 442a. Another stack of electrodes include another DC electrode 442b placed above another RF electrode 444b. Likewise, the electrodes in the 3D wafer ion trap 440 can be coated on respective wafer layers which can be stacked together. As shown, the ion's trapping position can define an upper field of view 406 and a lower field of view 408, both of which have the same open NA. In this example, the DC electrodes and the RF electrodes are configured to be in mirror positions about the ion's trapping position.

### Geometric Parameters of Simulated Ion Traps

The trapping performance of ion traps can be affected by their geometries, which can be characterized by a number of geometric parameters. As shown in FIGS. 3A-3D and 4A-4D, simulated non-SET ion traps can be characterized by three or more geometric parameters. In this simulation, a subset of the parameters (marked with Latin letters) are swept while the other parameters (marked with Greek letters) are fixed. For the ion traps with trench geometries (e.g., FIGS. 3B-3C and 4B-4C), investigation is also made on how trapping performance changes with the more relevant of the fixed parameters, e.g., by making multiple sweeps over the continuous parameters for different values of a fixed parameter.

As shown in FIG. 3B, the symmetric plain trench 320 can be characterized by four dimensions, the width c of the center (DC) electrode 326, the width d of the flank (RF) electrode 324a and 324b, the trench wall height 8, and the trench wall thickness α. The trench wall thickness α does not strongly affect the potential seen by the ion 302 because the ion 302 is shielded from all but the inner surfaces of the trench walls 305a, 305b. Thus, a fixed value α=100 μm, which is comparable to values used in the test fabrications described below, is used in all trench geometry ion trap simulations. A set of symmetric plain trench ion traps can be simulated at a fixed ion height, allowing c and d to vary for discrete values of β.

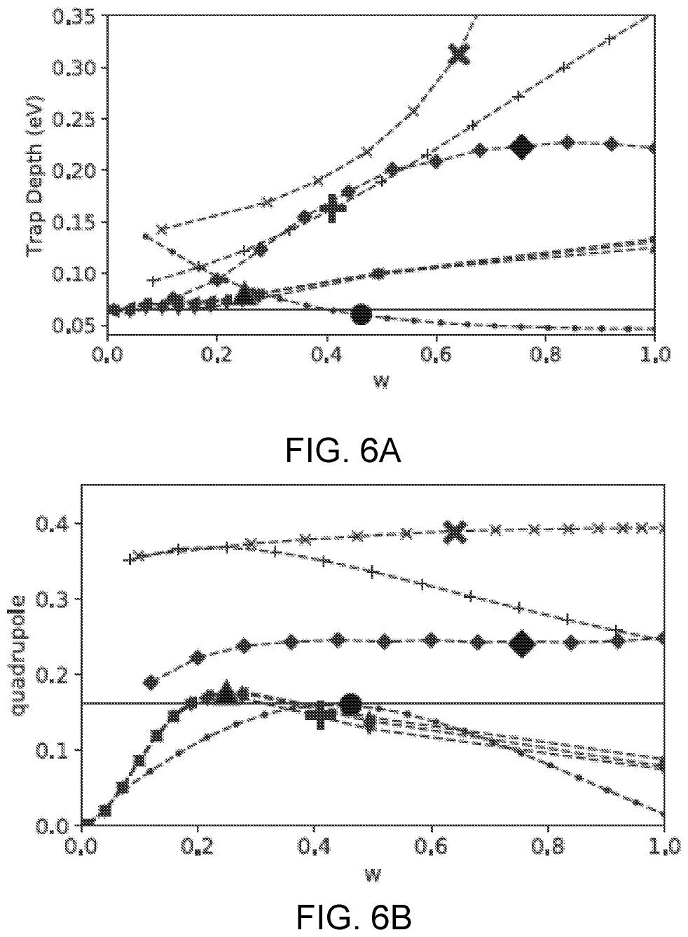

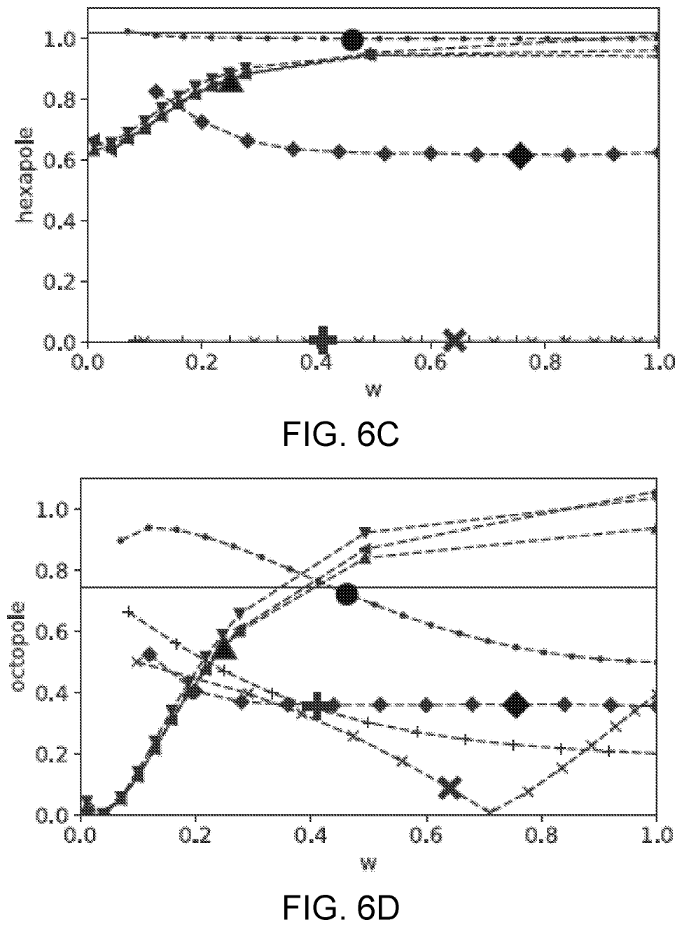

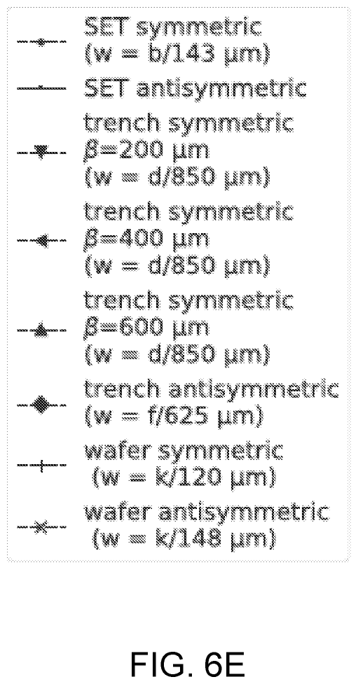

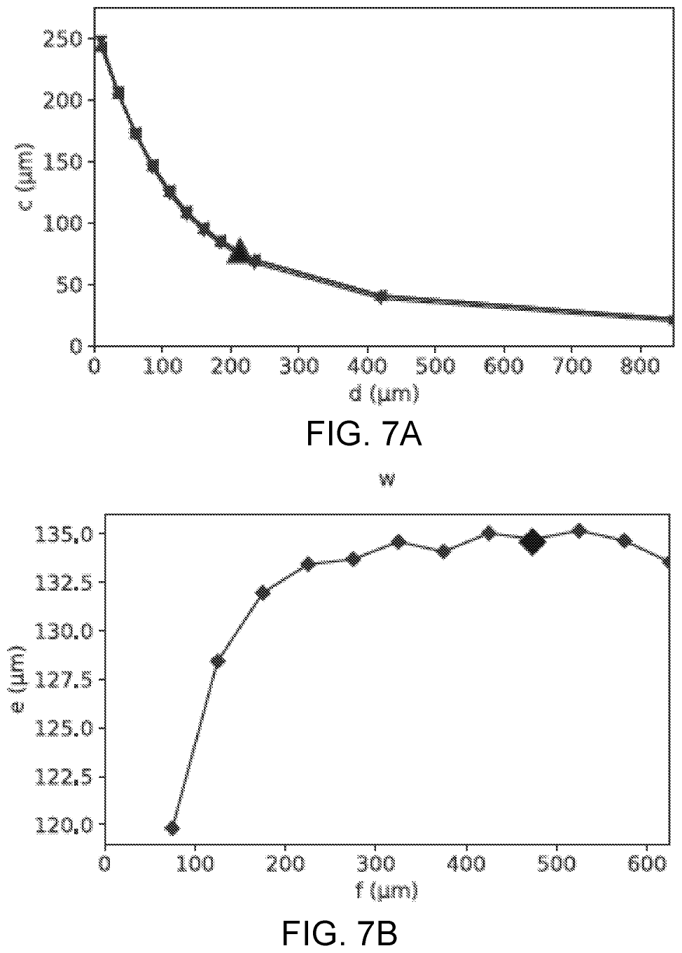

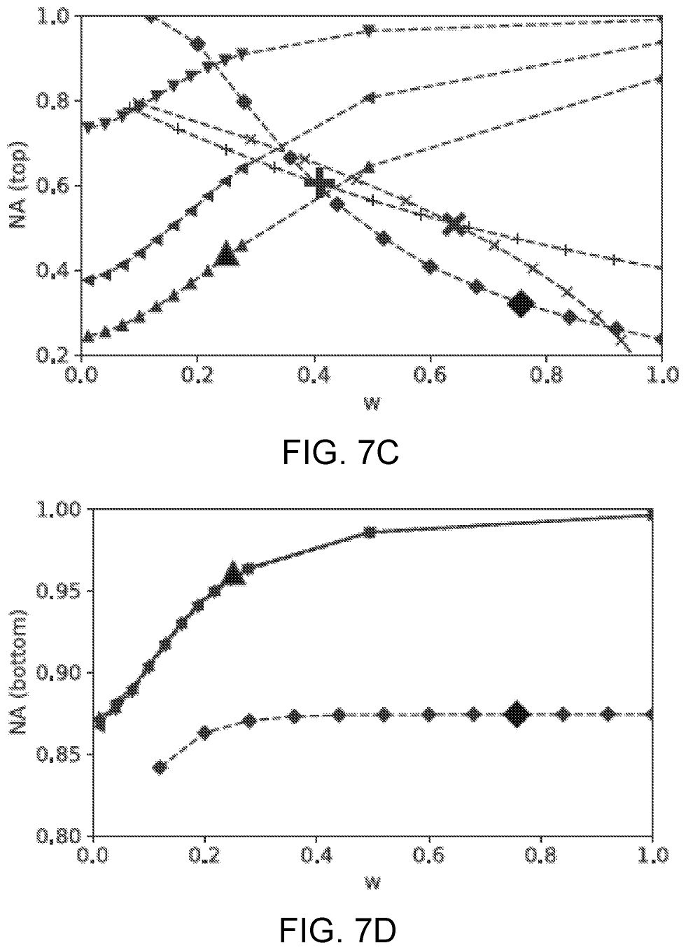

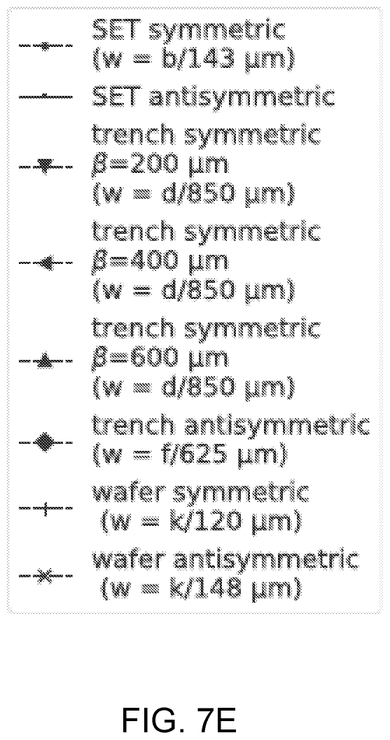

Unlike the symmetric design, the anti-symmetric plain trench ion trap 420 depicted in FIG. 4B can be characterized with just two parameters, the width e of the side electrode 426 and 428, and the trench wall height f. Simulation results show that the ion height in the anti-symmetric trench depends mainly on the width e (see, e.g., FIG. 7B). For example, past f≈200 μm, the ion height shows little dependency on f that is noticeable beyond numerical noise. The simulation results for the symmetric and anti-symmetric plain trench ion traps are shown in FIGS. 6A-6E and 7A-7E and described further below.

As shown in FIG. 3C, the symmetric stacked ion trench trap 330 can be characterized by four parameters: the trench wall height &, the trench width u, the height h of the base (DC) electrodes (e.g., 332a, 332b), and the height g of the middle (RF) electrodes (e.g., 334a, 334b).

As shown in FIG. 4C, the anti-symmetric stacked trench ion trap 430 can be characterized by three parameters: the trench wall height ξ, the height j of the base electrodes (e.g., 434a, 432b), and the trench width i.

The simulated ion traps have two regimes for which the separation between the ion and the nearest electrode is 75 μm. In the first regime, the ion is 75 μm from the floor electrode and the trench walls are further away. In the second regime, the ion is 75 μm from the trench walls (i.e., the trap width is set to 150 μm). Both regimes are considered in the anti-symmetric ion trap cases, but only the second region is considered in the symmetric ion trap cases (since the trapping performance in the other regime will clearly be worse).

For comparison purposes, the geometric parameters of SETs and 3D wafer traps can also be varied.

As shown in FIG. 3A, the geometry of the symmetric SET 310 can be characterized by two parameters: the width b of the (DC) electrode 312 immediately below the ion 302 and the width a of the immediately adjacent (RF) electrode 314. As shown in FIG. 4A, the geometry of the anti-symmetric SET 410 can be characterized by the width φ of the two (DC and RF) electrodes 412, 414 immediately below the ion 402.

For SETs, under the assumption of an infinitely large trap with no gaps between electrodes, simple closed-form expressions for the potential are available. While these closed-form expressions are used to calculate the parameters shown in FIGS. 6-11, simulations of the SETs are also performed using COMSOL as a way of benchmarking the BEM simulations. Specifically, the multipole expansions, trap heights, and trap depths are compared between the BEM-generated and analytic potentials for the symmetric SET. For most of the free parameter range, agreement across these parameters is within 2%. In the range where a<<b in the symmetric simple SET (see FIG. 3A), divergence approaches 10% due to the fact that the 1 μm electrode spacing present in all BEM simulations is no longer negligible. For a fixed ion height there is one free parameter in the symmetric SET and no free parameters in the anti-symmetric one.

As shown in FIGS. 3D and 4D, the geometry of both symmetric 3D wafer ion trap 340 and anti-symmetric 3D wafer ion trap 440 can be characterized by three parameters: the wafer thickness λ (which is also the thickness of electrode in each wafer layer), the wafer width or depth of the wafer t measured along the X-axis, and the spacing k between two adjacent wafer layers (assuming equal-distance between the wafer layers).

In the simulation, the wafer thickness is set to λ=50 μm, which is comparable to typical designs implemented in a lab. The wafer depth τ=1 mm is selected to be much larger than wafer thickness λ and inter-wafer spacing k so that the exact wafer depth is unimportant. Therefore, both symmetric and anti-symmetric 3D wafer ion trap designs have only one free parameter, the spacing k between wafers in a stack. The parameter k parameter is swept over while holding the ion-electrode distance constant.

### Simulation Results

The simulation compares the plain and stacked trench ion trap designs with established SET and wafer trap designs and assess their relative merits, and example simulation results are shown in FIGS. 6-11.

As an example, FIGS. 6-7 compare simulated parameters of SET ion traps versus the symmetric and anti-symmetric plain trench ion trap geometry. Specifically, FIG. 6A shows trap depth at a fixed radial frequency, FIG. 6B shows the quadrupole component (C₂) of the trapping potential at the ion, FIG. 6C shows the hexapole component

$$( {C}_{3}^{′} )$$

of trapping potential, and FIG. 6D shows the octupole component

$$( {C}_{4}^{′} )$$

of the trapping potential. FIG. 7A shows electrode dimensions at a constant ion-electrode separation for the symmetric plain trench ion trap. FIG. 7B shows electrode dimensions at a constant ion-electrode separation for the anti-symmetric plain trench ion trap, and FIGS. 7C-7D respectively show the NAs above and below the ion. Parameters are plotted against a generic geometric variable w, which is related to an electrode dimension of each trap as shown in the legend depicted in FIGS. 6E and 7E. The simulation results are shown with markers. Simulation points are connected with dashed lines only as a visual guide.

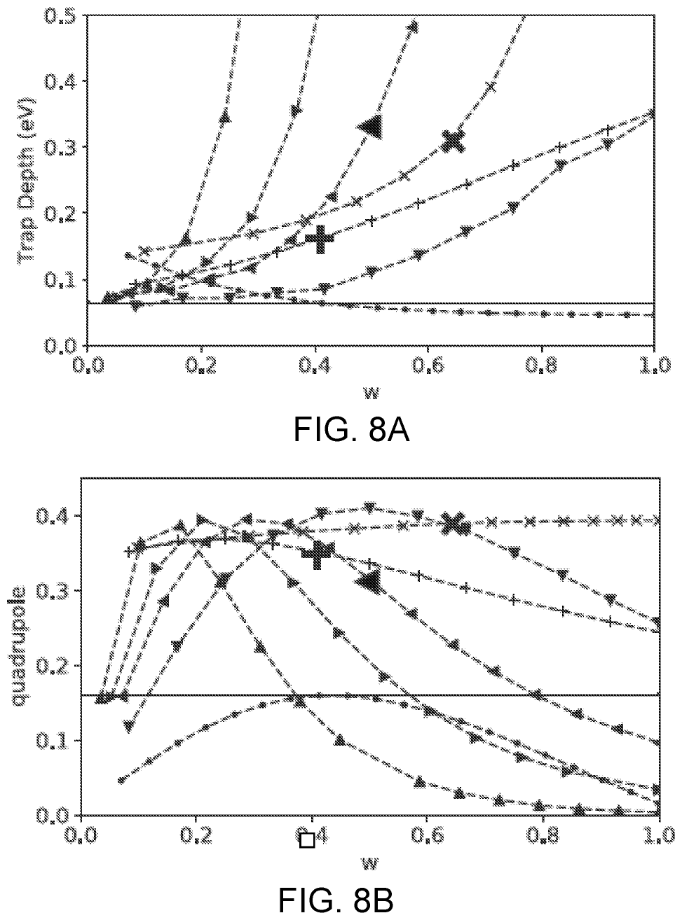

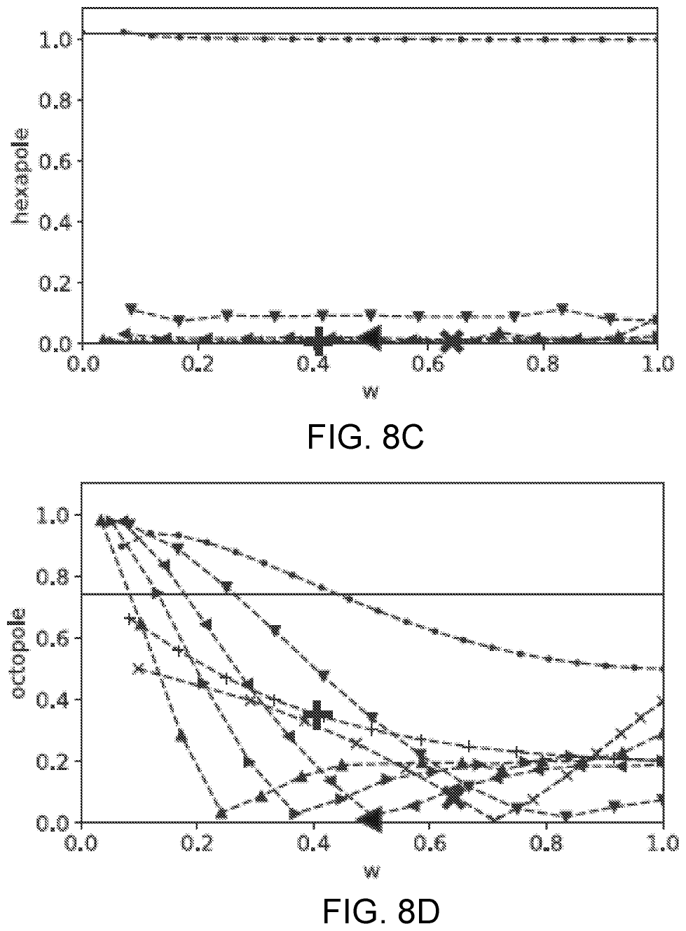

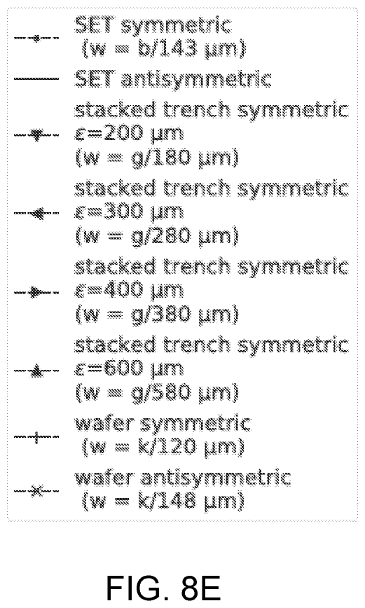

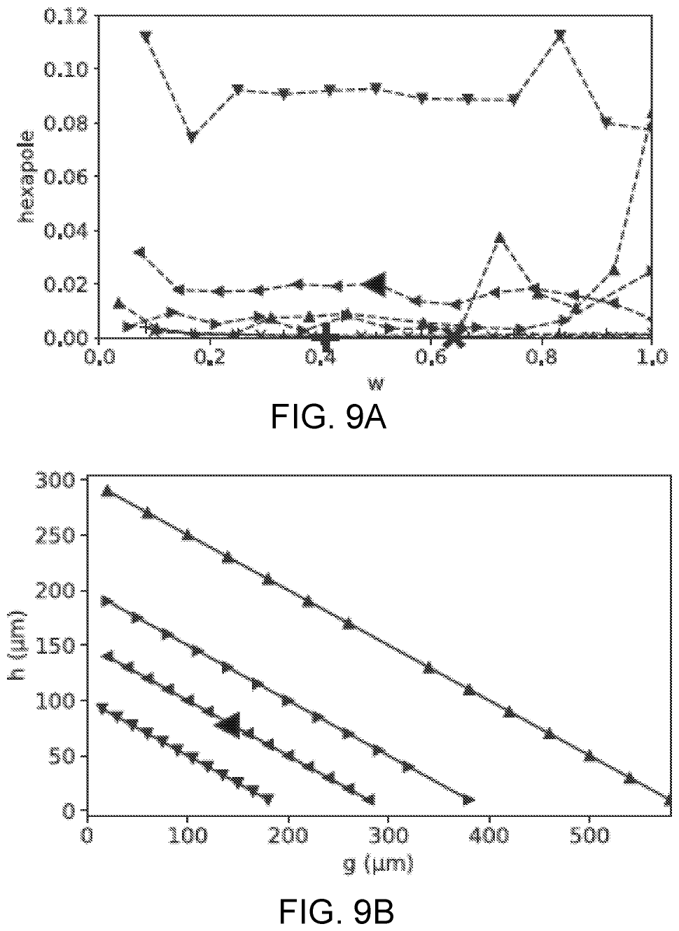

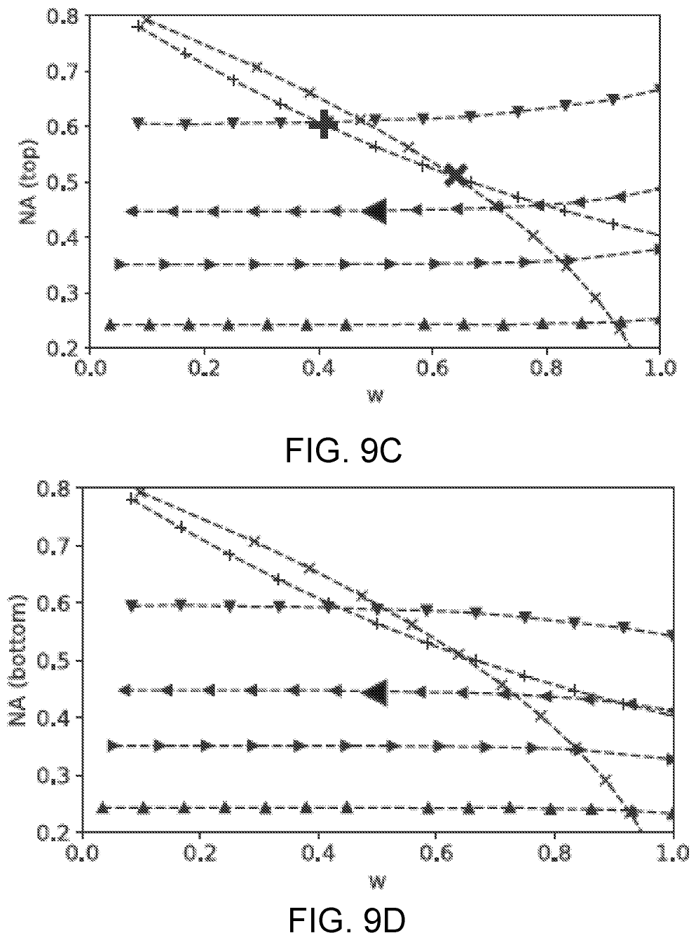

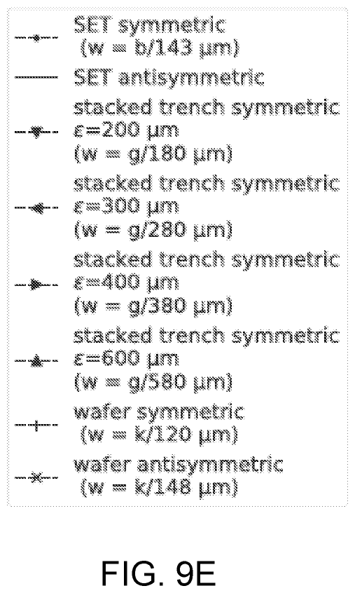

As another example, FIGS. 8-9 compare simulated parameters of SET ion traps and 3D wafer ion traps versus the ion traps with symmetric stacked trench geometry. Specifically, FIG. 8A shows trap depth at a fixed radial frequency, FIG. 8B shows the quadrupole component (C₂) of the trapping potential at the ion, FIG. 8C shows the hexapole component

$$( {C}_{3}^{′} )$$

of the trapping potential, and FIG. 8D shows the octupole component

$$( {C}_{4}^{′} )$$

of the trapping potential. FIG. 9A shows the hexapole component of the trapping potential, excluding the SET data to make the other series clearer, FIG. 9B shows the electrode dimensions at a constant ion-electrode separation for the symmetric stacked trench ion trap, and FIGS. 9C-9D respectively show the NAs above and below the ion. Similarly, parameters are plotted against a generic geometric variable w, which is related to an electrode dimension of each ion trap as shown in the legend depicted in FIGS. 8E and 9E. Simulation results are shown with markers. Simulation points are connected with dashed lines only as a visual guide.

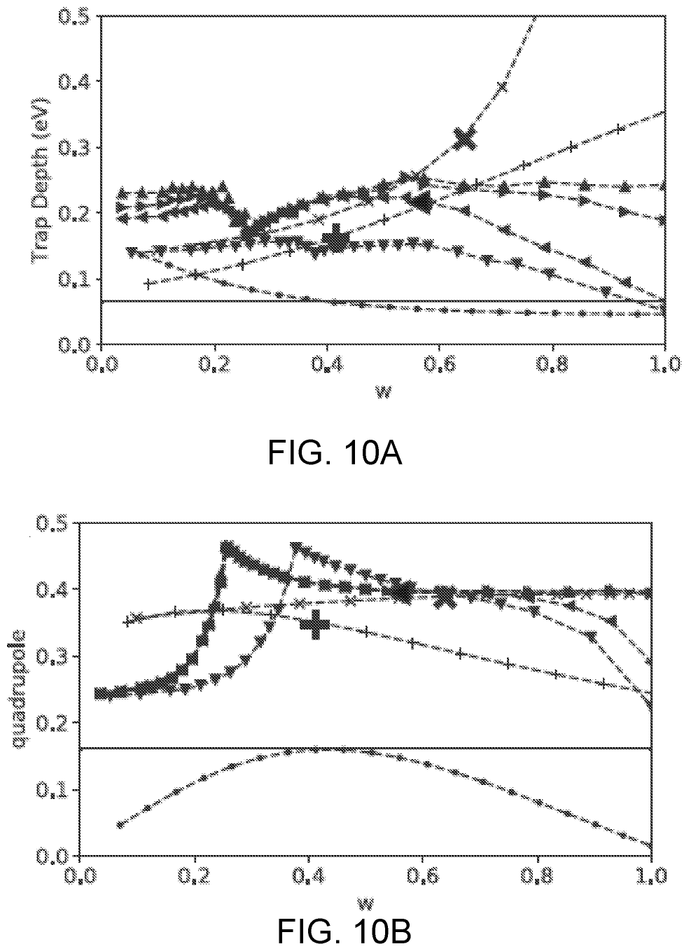

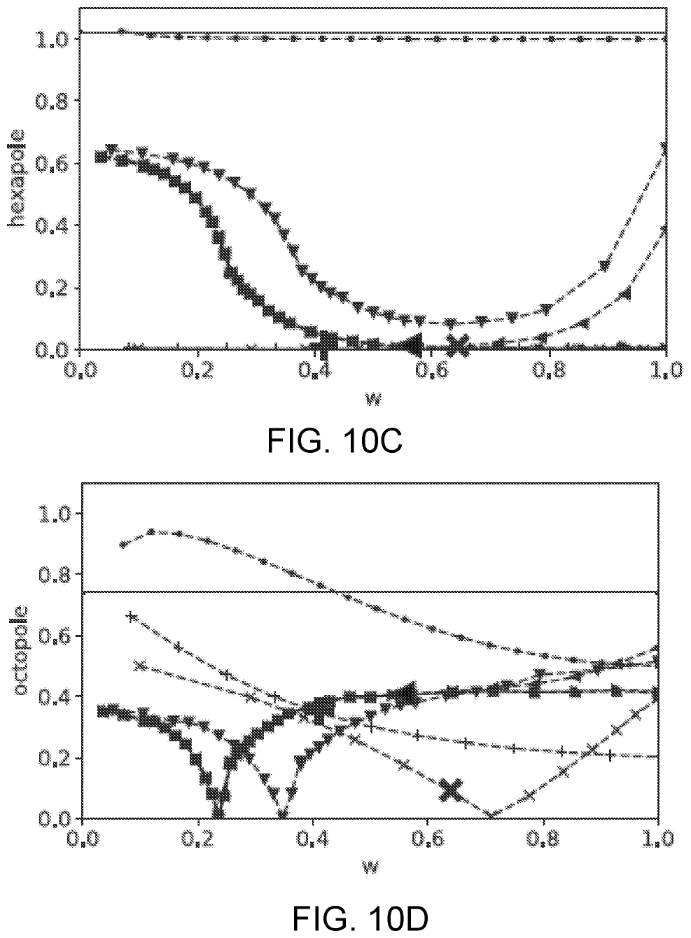

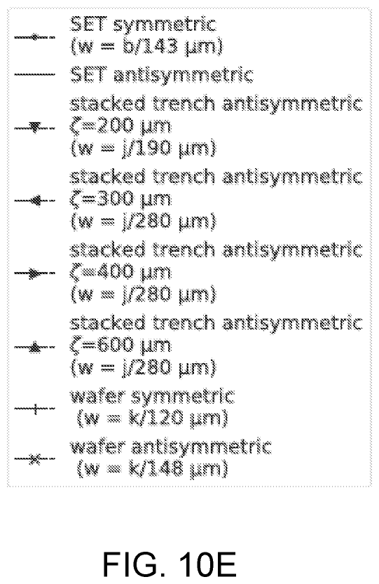

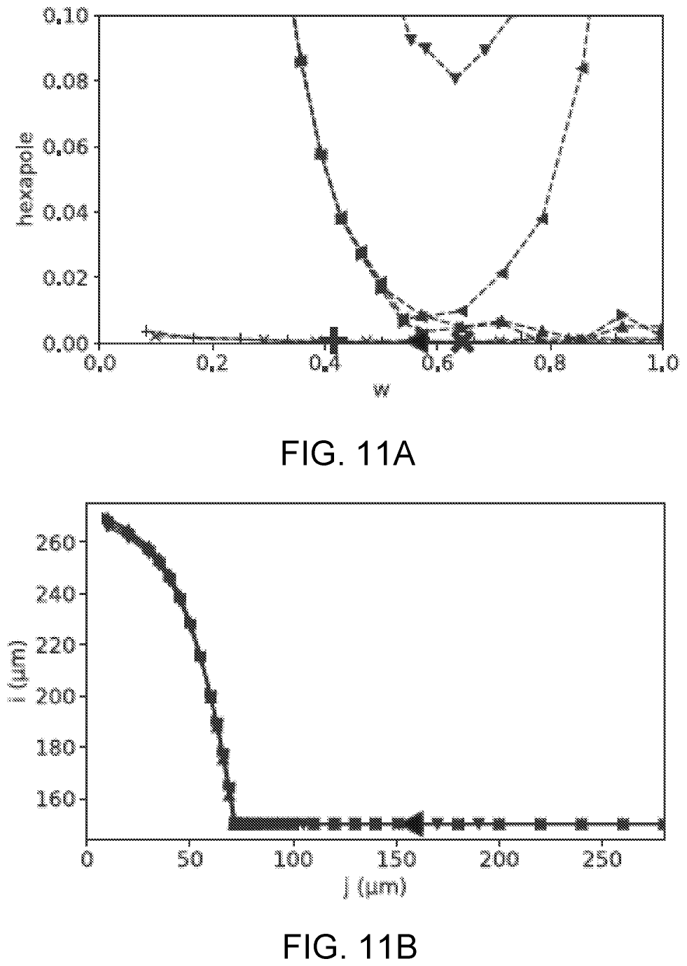

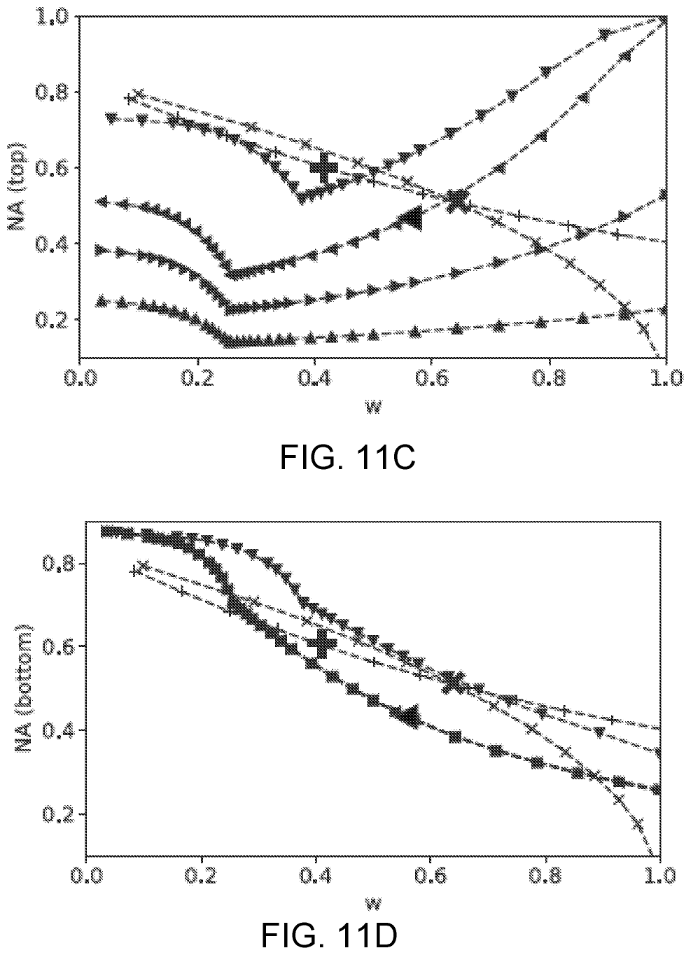

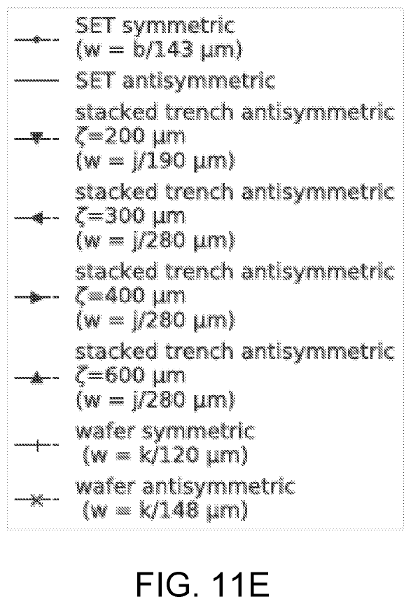

As a further example, FIGS. 10-11 compare simulated parameters of SET traps and wafer traps versus the ion traps with anti-symmetric stacked trench geometry. Specifically, FIG. 10A shows trap depth at a fixed radial frequency, FIG. 10B shows the quadrupole component (C₂) of the trapping potential at the ion, FIG. 10C shows the hexapole component

$$( {C}_{3}^{′} )$$

of the trapping potential, and FIG. 10D shows the octupole component

$$( {C}_{4}^{′} )$$

of the trapping potential. FIG. 11A shows the hexapole component of the trapping potential, excluding the SET data to make the other series clearer, FIG. 11B shows the electrode dimensions at a constant ion-electrode separation for the anti-symmetric stacked trench ion trap, and FIG. 11C-11D respectively show the NAs above and below the ion. Similarly, parameters are plotted against a generic geometric variable w, which is related to an electrode dimension of each trap as shown in the legend depicted in FIGS. 10E and 11E. Simulation results are shown with markers. Simulation points are connected with dashed lines only as a visual guide.

For easy comparison between these four sets of simulated geometries, a representative ion trap from each category is selected. These selected ion traps, in some qualitative way, optimize the balance between trap depth and quadrupole strength/purity. Although this selection is somewhat subjective, and optimum parameters may vary by application, they are unlikely to differ greatly from what have been chosen here. In FIGS. 6-11, simulation results corresponding to these selected representative ion traps are highlighted with larger markers. A table of values for these representative traps are shown in Table 1, and the associated dimensions are listed in Table 2 below.

TABLE 1
Summary of ion trap parameter calculations for the
selected representative SET, plain trench ion trap
(“Plain”), stacked trench ion trap (“Stacked”),
and 3D wafer ion trap (“Wafer”).

| | SET | | Plain | | Stacked | | Wafer | |
|---|---|---|---|---|---|---|---|---|
| | Sym | Anti | Sym | Anti | Sym | Anti | Sym | Anti |
| Depth (eV) | 0.06 | 0.07 | 0.08 | 0.23 | 0.33 | 0.22 | 0.16 | 0.39 |
| Quadrupole | 0.17 | 0.17 | 0.18 | 0.24 | 0.31 | 0.40 | 0.35 | 0.39 |
| Hexapole | 1.0 | 1.0 | 0.86 | 0.62 | 0.020 | 0.008 | 0.000 | 0.001 |
| Octupole | 0.75 | 0.75 | 0.55 | 0.36 | 0.024 | 0.407 | 0.344 | 0.007 |

TABLE 2
Dimensions of ion traps whose parameters
are summarized in Table 1.

| | |
|---|---|
| Ion Trap | Dimensions (μm) |

| | | |
|---|---|---|
| SET | Sym | a = 161.2, b = 59 |
| | Anti | φ = 75 |
| Plain | Sym | d = 77.3, c = 210, β = 600 |
| | Anti | e = 135.2, f = 525 |
| Stacked | Sym | g = 140, h = 80, ε = 300 |
| | Anti | i = 150, j = 160 |
| Wafer | Sym | k = 50 |
| | Anti | k = 53 |

From Table 1, it can be seen that all ion traps with trench geometries outperform SETs, evidenced by greater trap depth, improved geometry efficiency (e.g., larger quadrupole), and reduced anharmonicities (e.g., smaller hexapole and octupole).

Table 1 also shows that, for the symmetric plain trench ion trap, the improvement seems practically small. On the other hand, the anti-symmetric plain trench provides a significant improvement over the SET, offering ˜3 times the trap depth, ˜40% higher quadrupole strength, and ˜40% lower hexapole strength. Despite this it is still notably inferior to the wafer traps.

In addition, Table 1 shows that the stacked trench ion traps have very comparable performance to 3D wafer ion traps, with similar depth, quadrupole strength, and octupole terms. The hexapole term of the stacked trench ion traps may not be as low as the 3D wafer ion traps, where it can be zero by symmetry (though of course, manufacturing tolerances will set a practical limit). However, the hexapole term of the stacked trench ion traps still have a factor about 50-fold improvement over SETs, thus will still lead to drastic improvement in trap performance. One must also consider that the stray fields themselves have curvature terms which will at some point become the limit on trap frequency stability regardless of how small the hexapole and octupole terms are.

### Example Overall Method of Fabricating Ion Traps

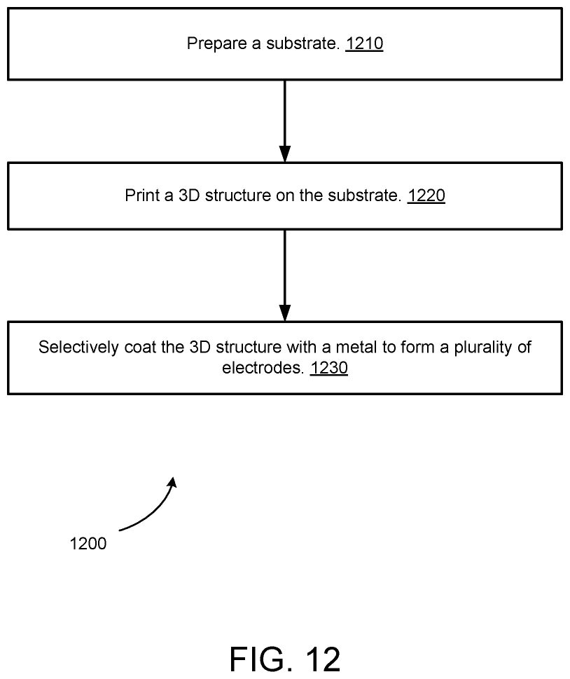

FIG. 12 is a flowchart depicting an overall method 1200 of fabricating ion traps described above.

At 1210, a substrate can be prepared. An example method of preparing the substrate is described more fully below.

The substrate can provide a supporting platform upon which the ion traps can be fabricated. Other control elements associated with the ion traps can also be integrated within the substrate (see, e.g., FIGS. 2A-2B). The substrate can be made of various materials. In certain examples, the substrate can include glass. In certain examples, the substrate can include silicon. In certain examples, the substrate can include polyamide. Other materials (e.g., sapphire, aluminum nitride, etc.) can also be used in the substrate.

At 1220, a 3D structure defining the geometrical shape of an ion trap can be printed on the substrate. For example, to fabricate an ion trap with a trench geometry, printing the 3D structure can include printing a first wall (e.g., 210, 305a or 405a) and a second wall (e.g., 210, 305b or 405b) extending vertically above a planar surface of the substrate to a wall height.

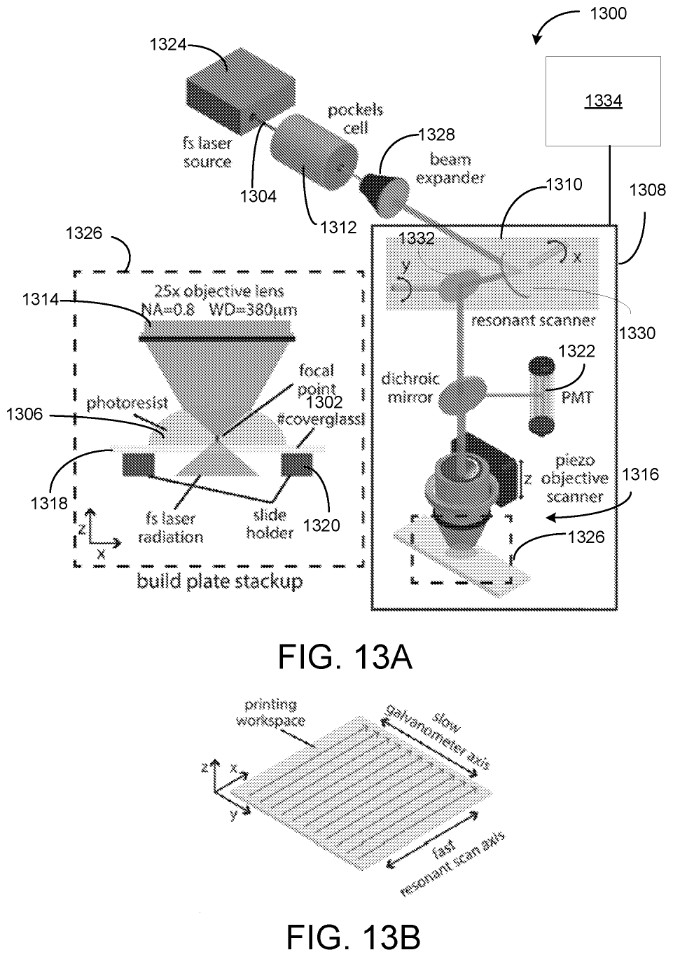

As described herein, the 3D structure of an ion trap can be formed by using a 3D printing technique. In some examples, the 3D printing technique can include raster-scanning direct laser writing lithography, e.g., by using a raster-scanning direct laser writing (rDLW) printer. The rDLW printer can be configured to print micron scale polymer structures at increased speeds (e.g., 8000 mm/s, which can be ten to thousands of times faster than other high-speed based direct laser writing printers), as discussed further below with reference to FIG. 13A.

While many commercially available additive manufacturing (e.g., 3D printing) systems can readily produce 3D structures, these 3D structures are either larger in scale (e.g., greater than the micron scale) or very small scale (e.g., nano scale). Thus, such 3D printing systems may not integrate well with micron scale electronics fabrication (e.g., microfabrication) techniques, such as photolithography, suitable to create the ion traps (e.g., 200, 320, 330, 420, 440, etc.) described herein. An increased scanning speed available with an rDLW printer allows for printing of ion trap 3D structures onto a prepared substrate with relatively high resolution on a micron scale.

At 1230, the printed 3D structure can be selectively coated or deposited with a metal (also referred to as “selective metallization”) to form a plurality of electrodes. As described herein, selectively coating the 3D structure includes coating at least one electrode on the first wall and coating at least one electrode on the second wall.

In certain examples, the metal used to form the plurality of electrodes can include gold. In certain examples, platinum, titanium, copper, aluminum, and/or other metals can also be used to form the plurality of electrodes.

As described herein, lithography can be used for selective metallization of the 3D structure. As an example, photolithography techniques can be used to metalize the 3D structure and electrically connect the metalized 3D structure with corresponding metal traces on the substrate, while maintaining non-metallized (insulated) space on the substrate, around the metallized 3D structure. As a result, ion traps and/or associated circuits can be produced with electrically insulated or separated electrodes or electrical components.

In some examples, the specific combination of 3D printing with the rDLW printer and metallization of the 3D structure via photolithography (e.g., using microfabrication techniques) allows the ion traps to be fabricated in an efficient manner.

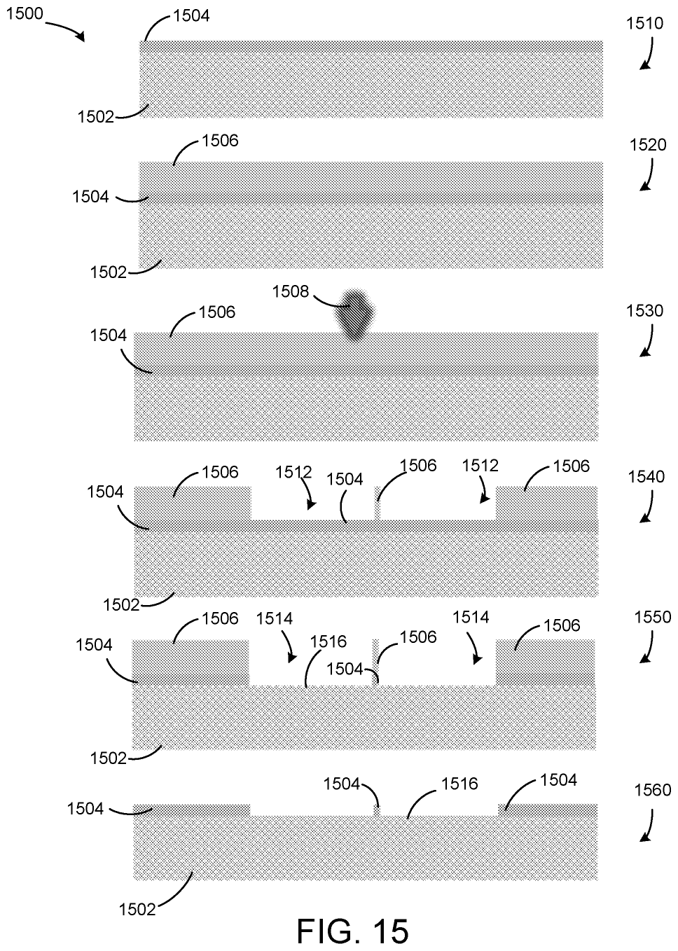

Further, as described in more detail below with reference to FIGS. 15-17, by combining 3D printing with described photolithography techniques, ion traps with electrodes and/or electronic components having specific external shapes or geometries can be created.

For example, the printed 3D structure can include one or more horizontal gaps (e.g., 232) on the first wall and the second wall, and the horizontal gaps can be configured to be parallel to the substrate. As another example, the printed 3D structure can include one or more vertical gaps (see, e.g., FIGS. 14A-14D and 17C-17E) on the first wall and the second wall, and the vertical gaps can be configured to be perpendicular to the substrate. As described further below, these horizontal gaps and/or vertical gaps can be used as “self-masking” during the selective metal deposition process. As a result, the metal coated on opposing sides of each gap can be electrically isolated from each other.

As described herein, selective metallization of a 3D structure can include applying (e.g., via sputtering) a metal to the surface of the 3D structure while not applying the metal to a portion of the surface of the substrate surrounding the 3D structure. As a result, multiple electrodes or electrical components on the substrate can be isolated, separated, and/or insulated from one other, thereby avoiding shorts between the electrodes. For example, adjacent electrodes or electrical components associate with an ion trap can be electrically isolated from one another by a gap and/or other insulating layer form on the 3D structure.

FIGS. 14A-14D show examples ion traps fabricated using the method 1200 described above. Specifically, FIGS. 14A-14D show scanning electron microscope (SEM) images of gold coated ion traps 1410 printed on glass, where each ion trap 1410 has a symmetric stacked trench geometry. For example, each trench wall of the ion trap 1410 can have top DC electrodes 1422 stacked on top of an RF electrode 1424 (see, e.g., FIGS. 14C-14D), which is further stacked on top another base DC electrode 1426 (see, e.g., FIG. 14C). As shown, the top DC electrodes 1422 can be segmented and electrically isolated from each other by vertical gaps 1428 that are perpendicular to the substrate. The top DC electrodes 1422 can be electrically isolated from the RF electrode 1424 by a horizontal gap 1428 which extends parallel to the substrate. Although the ion traps 1410 depicted in FIGS. 14A-14D have symmetric stacked trench geometry, it is to be understood that the ion traps 1410 can be fabricated with other geometric shapes.

As shown, many trenches 1420 are connected with X-junctions, and such structure can be incorporated in a large trapped-ion quantum charge-coupled device (QCCD). Specifically, the ion traps 1410 can be arranged to form an ion trap grid defined by a plurality of rows intersecting with a plurality of columns, wherein spaces between the opposing walls of respective ion traps are interconnected to form a grid of trenches 1420 along the plurality of rows and the plurality of columns. Specifically, the trench walls of some ion traps can be oriented along a first axis and the trench walls of the other ion traps can be oriented along a second axis that is perpendicular to the first axis. Neighboring trench walls that are perpendicular to each other can be connected end-to-end so as to form square shaped “trap wells,” and trenches (formed between opposing trench walls) can extend between these trap wells along either the first axis or the second axis. For example, as depicted in FIGS. 14B-14C, opposing trench walls 1412, 1414 of one ion trap can define a trench 1420a which intersects with another trench 1420b defined by two other trench walls 1416, 1418 of another ion trap.

### Example 3D Printing Technology Used for Fabricating Ion Traps

In certain examples, the plain trench ion traps can be fabricated using UV-LIGA (Ultraviolet-Lithographie, Galvanoformung, Abformung). UV-LIGA is a fabrication process where metal is electroplated inside a photoresist mold patterned using UV lithography. However, UV-LIGA cannot be readily applied to print the ion traps having the stacked trench geometry. Although in principle the stacked trench geometries may also be built using conventional MEMS techniques, in practice the ˜100s of μm vertical heights required are hard to achieve with oxide film deposition.

As described herein, the ion traps can be fabricated by first 3D printing a 3D structure of the ion trap directly onto a functional trap wafer using a dielectric material, and then selectively metalizing the 3D structure to create conductive electrode surfaces.

According to certain examples, the 3D printing technique used to print the 3D structure of an ion trap can include raster-scanning direct laser writing (rDLW). Direct laser writing printing technology is based on two photon polymerization (2PP), where a tightly focused laser is pulsed at femtosecond speeds while being scanned through a polymerizable liquid.

Specifically, the 3D structure of an ion trap can be 3D printed using a rDLW printer, such as the rDLW printer shown in FIG. 13A. For example, a predetermined 3D structure of the ion trap can be printed, layer-by-layer, onto the specified portions of the substrate. The predetermined 3D structure can be defined by a computer model of the 3D structure (e.g., 3D computer aided design (CAD) model) which is input into a computer or processor included in or in electronic communication with the rDLW printer. In some examples, the polymerizable liquid, and thus the resulting 3D printed 3D structure, can comprise a polymer (e.g., a photopolymer).

FIG. 13A shows an exemplary rDLW printer 1300 that can be used to print the 3D structure of an ion trap, such as the ion traps having the trench geometry described above. The rDLW printer 1300 can fabricate 3D objects by raster-scanning a focal point 1302 of a laser beam (e.g., femtosecond laser beam) 1304 through a build volume or build envelope 1306 (which, in some examples can comprise a volume of photoresist or other polymer), thereby defining the object structure line by line.

In some examples, as shown in FIG. 13A, the rDLW printer 1300 can comprise a standard two-photon microscope 408 with a resonant raster scanner 1310 and a high-speed/high-extinction-ratio laser power modulator 1312.

As described herein and as shown in FIG. 13B, Cartesian coordinates refer to directions and dimensions in the build envelope. The X and Y axes or directions are the perpendicular axes spanning a single focal plane of the perpendicular Z direction. The zoom setting of the microscope 1308 can determine the size of such X-Y plane, which can also be referred to as a workspace or field of view. As shown in FIG. 13B, X denotes the direction of the faster sweeps of the high-speed (e.g., about 8 kHz) resonant raster scanner 1310, and Y identifies the slower galvanometer-controlled row index.

The resonant raster scanner 1310, which in some examples can be a resonant and galvanometer scan module, can control the X-Y focal point 1302 of the laser beam 1304 within the build envelope 1306. For example, the resonant raster scanner 1310 can comprise a resonant mirror 1330 which controls the focal point 1302 along the X-axis and a galvanometer mirror 1332 which controls the focal point 1302 point along the Y-axis.

As shown in the detail view of a build stack plate 1326 of the rDLW printer 1300, an immersion objective lens 1314, which in some examples can include a refraction compensation ring, can be used for both printing and imaging.

The rDLW can further comprise a piezo-scanner 1316 which can enable fast, precise Z-axis positioning of the objective lens 1314 (and hence the focal plane) during printing. In some examples, the substrate of the 3D electronic device can be positioned on a build plate 1318 which is supported at its edges by one or more holding mechanisms 1320. In other examples, the substrate of the 3D electronic device can replace the build plate and be connected to the one or more holding mechanisms 1320.

In some circumstances, the rDLW printer 1300 can include an imaging device 1322 which can be configured to image the workspace and printed objects, such as a photomultiplier camera (FIG. 13A).

The rDLW printer 1300 can have a laser source (e.g., laser system) 1324 configured to produce the laser beam 1304. The laser beam 1304 can be configured to have programmable wavelength, pulse width, repetition rate, and/or energy. In one particular example, the laser source 1324 can provide the laser beam 1304 at about 780 nm wavelength, 100 fs pulse width, 80 Mhz repetition rate, and about 100 mW energy. In certain examples, the laser source 1324 can provide the laser radiation for both polymerization and visualization of the photoresist and printed objects/structures. In some examples, the beam intensity of the laser beam 1304 can be modulated by the power modulator 1312, which can be configured as a Pockels cell 1312.

In some embodiments, to flatten the profile and improve collimation of the laser beam 1304, the laser beam 1304 can be routed through a beam expander 1328 before entering the optics of the resonant raster scanner 1310.

The rDLW printer (or printer system) 1300 can comprise a control system 1334. The control system can comprise a data acquisition system that interfaces the above-described components of the rDLW printer with a processor and memory (e.g., data storage) of the control system 1334. The memory of the control system 1334 can include computer-readable instructions for converting a received CAD model (e.g., via a received stereolithography (STL) file) of a desired 3D structure to be printed into commands or actuation signals sent from the processor of the control system 1334 to the components of the rDLW printer (e.g., the laser source 1324, power modulator 1312, piezo-scanner 1316, and/or the like). Thus, the rDLW printer 1300 can 3D print the 3D structure defined in the received computer model.

As a result, the rDLW printer 1300 can be capable of printing (referred to herein as 3D printing) complex, micron-scale structures efficiently and at a high resolution. For example, in certain circumstances, the resonant raster scanner 1310 of the rDLW printer 1300 can scan at approximately 8 kHz, thereby bringing the rDLW printer's speed up to about 8,000 mm/s. This print speed can be tens to thousands of times faster than other high-speed galvanometer based DLW printers. The increased scanning speed of the rDLW printer 1300 can reduce the amount of time for polymerization of the polymer liquid (e.g., photoresist) in the build envelope 1306 to occur, as well as allowing for a reduction in energy being delivered to the polymer liquid during each pass of the laser beam 1304. This can result in more robust 3D structures which adhere better to the underlying substrate.

According to certain examples, a hybrid resist can be used in the 3D printing process, based on Ormocomp photoresist (Microchem). In certain cases, the hybrid resist can be added with a photoinitator, such as 2.4.6-trimethylbenzoyl phosphine oxide (TPO) (Sigma), a stabilizing agent, 3,5-Di-tert-butyl-4-hydroxytoluene (BHT), and Fluorescein (Sigma) for in situ imaging during printing.

Although a specific rDLW printer 1300 is described above, it is to be understood that the 3D structure of an ion trap can also be 3D printed with another type of 3D printing device.

In operation, the processor of the control system of the 3D printer (e.g., the control system 1334 of the rDLW printer 1300) can receive a CAD model (e.g., via a STL file), which can define a specified (predefined) 3D structure to be printed onto the substrate. The 3D printer can then be actuated (e.g., via electrical signals sent to components of the 3D printer from the control system) to print the predetermined 3D structure onto the substrate, layer by layer. As an example, by utilizing 3D printing with the above-described rDLW printer to print 3D structures defined by a received computer model, a wide variety of print geometries with intricate features (e.g., gaps, pores, internal channels, and the like) are possible in a reduced time frame (as compared to other microfabrication processes, such as MEMS, which may utilize sequences of layering, masking, and etching to produce multi-layer structures, but in a much more time intensive, complex, and expensive manner). Further, by utilizing 3D printing to create the 3D structures for the electrodes, the electrodes can be customized for ion traps of any geometry. For example, almost limitless (for the space allowed by a print pad on the substrate) geometries can be created in a CAD file and then printed by the 3D printer in a rapid manner.

### Example Dielectric Material Used for Printing 3D Structure of the Ion Traps

According to certain examples, organically modified ceramic (also known as ormocer), which is a silica-based material, can be used as a photopolymerized dielectric material for 3D printing. For example, for an ion trap with a trench geometry, both trench walls can be 3D printed using ormocer.

Ormocer is a suitable material for 3D printing of disclosed ion traps because of its special properties. The high RF frequencies (e.g., between about 10-100 MHZ) and voltages (e.g., between about 10-1000 V) applied to ion trap electrodes places stringent requirements on the electrical and thermal properties of any dielectrics used. High dielectric strength is required to avoid breakdown. High resistivity and low loss tangent avoid direct heating of the dielectric. A low dielectric constant reduces parasitic capacitance, requiring less current to drive the electrodes, and thus lower Ohmic losses in the electrode metal. Additionally, a high thermal conductivity ensures any heating from losses is minimized. Ormocer properties can be formulation dependent. According to certain examples, ormocer can be formulated to have the property values (expressed in ranges) listed in Table 3 below.

TABLE 3
Example electrical and thermal properties of ormocer.

| | |
|---|---|
| Relative permittivity | Between 2 and 4 |
| Loss tangent | Between 0.003 and 0.005 |
| Dielectric strength (V/cm) | Between 7 × 10⁵ and 10 × 10⁵ |
| Bulk resistivity (Ω · cm) | Between 3 × 10¹⁶ and 5 × 10¹⁶ |
| Thermal conductivity (W/m · K) | Between 2 and 3 |

In particular formulation examples, the relative permittivity of ormocer used for 3D printing of disclosed ion traps can be 2.5, or 2.7, or 3.1. In particular formulation examples, the loss tangent of ormocer used for 3D printing of disclosed ion traps can be 0.0035, or 0.00397, or 0.004. In one particular formulation example, the dielectric strength of ormocer used for 3D printing of disclosed ion traps can be 8.7×10⁵ V/cm. In one particular formulation example, the bulk resistivity of ormocer used for 3D printing of disclosed ion traps can be 4.5×10¹⁶ Ω·cm. In one particular formulation example, the thermal conductivity of ormocer used for 3D printing of disclosed ion traps can be 2.3.

For room temperature operation, outgassing can be kept low to ensure ultra-high vacuum pressures can be reached and the material can withstand ˜200° C. vacuum bakes. Low outgassing can also reduce the chance of contaminating metal electrode surfaces, which can play a role in anomalous heating. The organic cross-linked structure of ormocer can reduce outgassing and makes ormocer fit for vacuum processes. In addition, ormocer can remain stable to >300° C. For cryogenic operation, vacuum compatibility is much less of an issue but the structure is configured be able to survive repeated temperature cycles without structural failure.

### Example Substrate Preparation

FIG. 15 schematically illustrates an example method 1500 of preparing a substrate in fabrication of an ion trap with a trench geometry.

As shown in FIG. 15, at 1510, a sacrificial layer 1504 can be applied, e.g., via sputtering, onto a top surface of a substrate 1502. In certain examples, the sacrificial layer 1504 can include a metal such as aluminum, chromium, copper, etc.

At 1520, a positive photoresist 1506 can be deposited on or spun onto a top surface of the sacrificial layer 1504, thereby covering the sacrificial layer 1504.

The substrate 1502 having a photoresist material (e.g., the positive photoresist 1506) can also be referred to as a “photolithographic substrate” which supports photopatterning. For example, one or more traces can be photopatterned on the positive photoresist 1506. The one or more traces can define at least a top contour of a 3D structure of an ion trap.

In certain examples, the one or more photopatterned traces can further define at least one metal trace on the substrate. The at least one metal trace can be configured to be connected to a portion of the 3D structure where an electrode is formed.

At 1530, a laser source 1508 can be directed at the assembly and used to expose and trace specified regions of the positive photoresist 1506 which cover a portion of the substrate 1502 where electrical contacts and the 3D structure of the ion trap are desired to be positioned (e.g., the one or more traces defining the top contour of a 3D structure). In other words, the laser source 1508 can be used at 1530 to etch or trace (e.g., raster scan) and define a desired location for the electrical contacts, traces, and/or the 3D structure of the ion trap on the substrate 1502.

At 1540, the positive photoresist 1506 on the substrate 1502 can be exposed to a developer solution (e.g., via submersion, washing, or the like). As a result, the portions of the positive photoresist 1506 that were exposed to the laser source 1508 (e.g., the portions of the positive photoresist defined by the one or more photopatterned traces and exposed to the laser source 1508) are removed, leaving behind one or more openings (or windows) 1512 in the positive photoresist 1506 to expose the underlying sacrificial metal layer 1504.

At 1550, the assembly can be exposed to an acidic metal etchant, thereby removing a portion of the sacrificial metal layer 1504 that is exposed by the openings 1512. In this way, the positive photoresist 1506 can serve as an etch mask for the sacrificial metal layer 1504 in the acidic metal etchant.

At 1560, the remaining positive photoresist 1506 can then be removed by exposure to a developing solution (e.g., developer). As a result, one or more openings 1514 can be formed in the sacrificial layer 1504 to expose a top surface 1516 of the underlying substrate 1502.

In some examples, the substrate 1502 can comprise preconfigured and photopatterned metal traces and/or electrical contacts. The method 1500 can be used to etch through the sacrificial layer 1504 to expose the underlying electrical traces and/or electrical contacts, some of which can be connected to a 3D structure which will be printed on the top surface 1516, as described below.

### Example 3D Printing and Selective Metallization

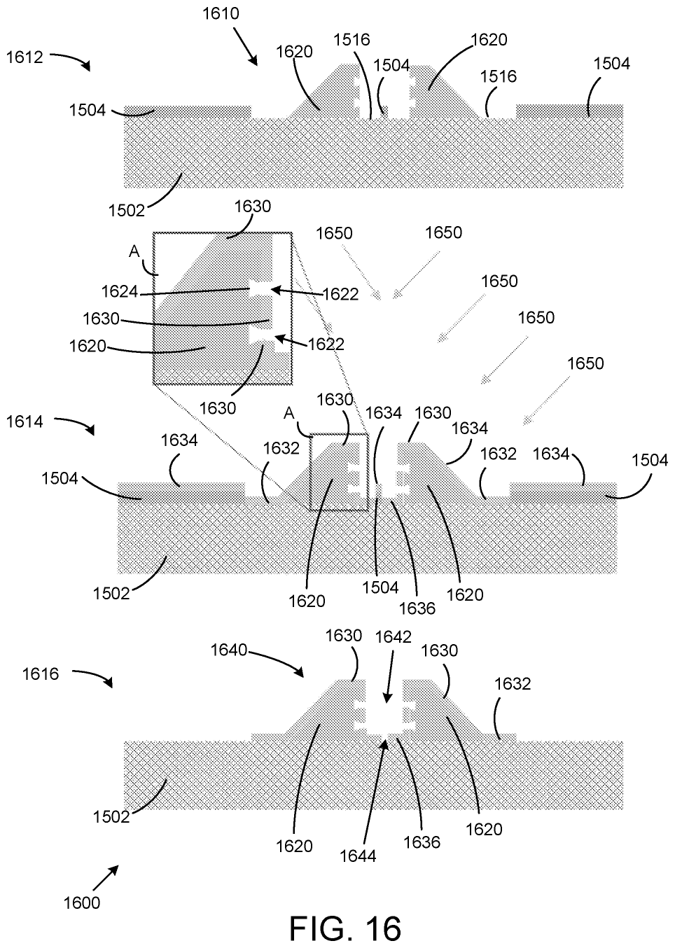

FIG. 16 schematically illustrates an example process 1600 of 3D printing a 3D structure and selectively metalizing the 3D structure in fabrication of a trench geometry ion trap.

At 1612, a 3D structure 1610 of an ion trap can be printed (e.g., by using the rDLW printer depicted in FIG. 13A) onto the exposed top surface 1516 of the substrate 1502. In the depicted example, the 3D structure 1610 has a trench geometry defined by two trench walls 1620 extending vertically above the top surface 1516 and spaced away from one another. Additionally, the printed 3D structure 1610 can include one or more gaps 1622 on the trench walls (see, e.g., inset A). The gaps 1622 can extend parallel and/or perpendicular to the top surface 1516 of the substrate 1502. Although the 3D structure 1610 depicted in FIG. 16 has a specific geometry, it should be understood that this shape of the 3D structure 1610 is exemplary and other geometries for the 3D structure 1610 are possible.

At 1614, the 3D structure 1610 can be selectively coated by a metal, which can include platinum, titanium, gold, copper, aluminum, silver, or the like. In certain examples, the metal can be sputtered over the surface of the whole assembly (e.g., including the remaining sacrificial layer 1504 and the exposed 3D structure 1610), thereby forming a metal layer 1634 over the remaining sacrificial layer 1504 and the 3D structure 1610.

For example, selectively coating the 3D structure 1610 can include coating selective portions of the trench walls 1620 so as to form one or more electrodes 1630 on the trench walls 1620.

In certain examples, the electrodes 1630 coated on the trench walls 1620 can extend vertically through the entire wall height of the respective trench walls 1620 (see, e.g., FIGS. 3B and 4B).

In certain examples, the electrodes 1630 coated on each trench wall 1620 can form two or more stacked electrodes which are electrically isolated from one another (see, e.g., FIGS. 3C and 4C), e.g., via the gaps 1622 formed on the trench walls 1620.

In certain cases, selectively coating the 3D structure 1610 can also include selectively coating a trench floor of the 3D structure 1610. The trench floor of the 3D structure 1610 can be defined by the top surface 1516 of the substrate 1502 extending between the two trench walls 1620.

As described herein, selectively coating the trench floor can include forming one or more floor electrodes 1636 on the trench floor. In certain examples, selectively coating the trench floor can include forming at least one gap 1644 between the one or more floor electrodes 1636 so as to expose the substrate 1502 underneath the gap 1644. The gap 1644 can create electrical insulation between neighboring floor electrodes 1636. In certain cases, the gap 1644 can also be used for laser beam access and/or fluorescence collection.

In certain examples, selectively coating the trench floor can include electrically isolating at least one of the floor electrodes 1636 from the electrodes 1630 disposed on the trench walls (see, e.g., FIGS. 3B and 4B). In certain examples, selectively coating the trench floor can include electrically coupling (or integrating) at least one of the floor electrodes 1636 to at least one of the electrodes 1630 disposed on one of the trench walls 1620 (see, e.g., FIGS. 3C and 4C).

In certain examples, selectively coating the 3D structure 1610 can include coating one or more metal traces 1632 on the substrate 1502. The one or more metal traces 1632 can be connected to at least some of the electrodes 1630 coated on the trench walls 1620. Thus, the selective metallization process described herein can simultaneously form electrodes (e.g., 1630, 1636) of an ion trap and connected conducting wires (e.g., the metal traces 1632) on the substrate.

At least one of the electrodes 1630, 1636 can be configured as a DC electrode, e.g., by connecting the electrode to a DC voltage source. Additionally, at least one of the electrodes 1630, 1636 can be configured as an RF electrode, e.g., by connecting the electrode to an RF voltage source. The arrange of the DC and RF electrodes can be configured to be symmetric or anti-symmetric, as described above with reference to FIGS. 3B-3C and 4B-4C.

In certain examples, selective metallization of the 3D structure 1610 can be performed by using a directional metal deposition process (e.g., the metal deposition can be configured to be directional, as indicated by the arrows 1650), such as e-beam evaporation, coupled with angle evaporation techniques. For example, the 3D structure 1610 can be selectively metalized by applying electron beam evaporation to deposit the metal on selected portions of the 3D structure 1610.

In certain examples, angle evaporation can be used to create insulated gaps 1644 between the electrodes 1630. For example, as illustrated in the inset A, the gaps 1622 can be configured to have a sufficient depth and/or having a slight overhang. The direction of the metal deposition can be adjusted so that at least a portion of an inside wall 1624 of the gap 1622 is not coated by the metal, thereby creating an electrical insulation between metal coated on opposite sides of the gap 1622. In other words, the 3D structure 1610 can be configured to be self-masking where the gaps 1622 between electrodes 1630 can be made deep enough (or with an undercut) such that directional deposition of metal onto the 3D structure 1610 will not cause shorting between the electrodes 1630.

After metallization, as shown at 1616, the remaining sacrificial layer 1504 can be removed (e.g., lifted off the substrate 1502), thereby revealing a selectively metallized ion trap 1640 comprising the 3D printed 3D structure 1610 coated with electrodes 1630 (which may be connected with metal traces 1632). On the substrate, isolation between electrodes can be achieved using the liftoff process. For example, as shown in 1614, between the trench walls 1620, a small sacrificial layer 1504 is sandwiched between two floor electrodes 1636 (and coated with a small metal layer 1634). Lifting the sacrificial layer 1504 off the substrate 1502 can expose the gap 1644 which isolates the floor electrodes 1636.

FIGS. 17A-17E further illustrate various steps for fabricating a trench geometry ion trap 1710 on a substrate 1720, according to one example. As shown, the substrate 1720 defines an X-Y plane, and the ion trap 1710 extends vertically above the substrate along the Z-axis. For simplicity, only a short section of the ion trap 1710 along the Y-axis is shown (i.e., the ion trap 1710 can have a larger length measured along the Y-axis than what is depicted in FIG. 17E). Insets are shown (in marked squares) to illustrate the liftoff process in more detail.

FIG. 17A shows the substrate 1720 comprising a silicon wafer 1722 with a SiO2 dielectric layer and integrated electrode routing 1724 and vias 1724 up to the surface. The silicon wafer 1722 can be fabricated using standard CMOS process as known in the art.

FIG. 17B shows that a sacrificial layer 1730 (e.g., comprising aluminum) can be deposited on the substrate 1720 and patterned to define a plurality of gaps 1732 between electrodes, e.g., by using the substrate preparation method 1500 described above.

FIG. 17C shows that a 3D structure 1740 can be printed on the substrate 1720, e.g., by using the rDLW printer 1300 to print an ormocer dielectric material, as described above. As shown, the 3D structure 1740 can include two opposing trench walls 1742 that define a trench 1744 in-between. In the depicted example, each trench wall 1742 can be segmented into smaller portions by two horizontal gaps 1746 (parallel to the substrate 1720) and a plurality of vertical gaps 1748 (perpendicular to the substrate 1720).

FIG. 17D shows that a metal layer 1750 (e.g., gold) can be deposited from multiple angles (e.g., by using directional metal deposition process coupled with angle evaporation techniques) to coat selected surfaces of the trench walls 1742, the trench floor 1752 between the trench walls 1742, and any exposed top surface of the substrate 1720. After metal deposition, the portions segmented by the gaps 1746, 1748 can form a plurality of vertically stacked (along Z-direction) and/or horizontally segmented (along Y-direction) electrodes 1754. As described above, the gaps 1746, 1748 can be used for self-masking when creating the electrically isolated electrodes 1754.

FIG. 17E shows that the sacrificial layer 1730 can be etched to allow liftoff of the metal layer 1750 over the gaps 1732 between the electrodes 1754. As a result, the ion trap 1710 with a trench geometry defined by the 3D printed 3D structure 1740 can be created on the substrate 1720. Optics for laser delivery and fluorescence detection can be further integrated to the ion trap 1710, as described above.

The process described above is scalable and compatible with modern wafer designs, thus enabling these devices to be added as a final step to current ion trap technology.

### EXAMPLE IMPLEMENTATIONS

Although the operations of some of the disclosed methods are described in a particular, sequential order for convenient presentation, such manner of description encompasses rearrangement, unless a particular ordering is required by specific language set forth herein. For example, operations described sequentially can in some cases be rearranged or performed concurrently.

### Additional Examples of the Disclosed Technology

In view of the above described implementations of the disclosed subject matter, this application discloses the additional examples enumerated below. It should be noted that one feature of an example in isolation or more than one feature of the example taken in combination and, optionally, in combination with one or more features of one or more further examples are further examples also falling within the disclosure of this application.

Example 1. An apparatus, comprising: a first wall and a second wall extending from a planar surface of a substrate to a wall height; and a plurality of electrodes disposed on the first wall and the second wall, wherein the first wall and the second wall are spaced apart from one another along a first axis on the planar surface, wherein the plurality of electrodes are configured to generate an electric field to trap an ion at a trapping position located between the first wall and the second wall, wherein a vertical distance between the trapping position and the planar surface of the substrate is smaller than the wall height.

Example 2. The apparatus of example 1, wherein the plurality of electrodes comprises one or more direct current (DC) electrodes configured to generate a DC component of the electric field and one or more radial frequency (RF) electrodes configured to generate an RF component of the electric field.

Example 3. The apparatus of example 2, wherein the one or more RF electrodes are connected to a common RF voltage source.

Example 4. The apparatus of any one of examples 2-3, wherein the one or more DC electrodes are connected to a common DC voltage source.

Example 5. The apparatus of any one of examples 2-3, wherein at least some of the one or more DC electrodes are connected to different DC voltage sources.

Example 6. The apparatus of any one of examples 1-5, wherein the first wall and the second wall extend along a second axis on the planar surface of the substrate, the second axis being perpendicular to the first axis.

Example 7. The apparatus of example 6, wherein a length of the first wall and the second wall measured along the second axis is larger than a width between the first wall and the second wall measured along the first axis.

Example 8. The apparatus of example 7, wherein the length of the first wall and the second wall measured along the second axis is at least five times the width between the first wall and the second wall measured along the first axis.

Example 9. The apparatus of any one of examples 7-8, wherein each of the first wall and the second wall comprises a plurality of segmented portions along the second axis, wherein a plurality of DC electrodes that are electrically insulated from each other are disposed on respective segmented portions.

Example 10. The apparatus of any one of examples 6-9, wherein the trapping position is located on a trapping axis, wherein the trapping axis extends parallel to the second axis and is located halfway between the first wall and the second wall.

Example 11. The apparatus of any one of examples 1-10, wherein an inner surface of the first wall faces an inner surface of the second wall, wherein the inner surface of the first wall and the inner surface of the second wall are perpendicular to the planar surface of the substrate.

Example 12. The apparatus of example 11, wherein each of the inner surface of the first wall and the inner surface of the second wall comprises one or more cuts extending parallel to the planar surface of the substrate, wherein each cut separates at least one upper electrode above the cut and at least one lower electrode below the cut, wherein the at least one upper electrode is electrically insulated from the at least one lower electrode.

Example 13. The apparatus of any one of examples 1-12, wherein a distance between the first wall and the second wall defines a trap width, wherein the trap width is between 25 μm and 1 mm, inclusive.

Example 14. The apparatus of example 13, wherein the trap width is between 50 μm and 150 μm, inclusive.

Example 15. The apparatus of any one of examples 13-14, wherein the wall height is at least 50% of the trap width.

Example 16. The apparatus of example 15, wherein the wall height is about the same as the trap width.

Example 17. The apparatus of example 15, wherein the wall height is larger than the trap width.

Example 18. The apparatus of any one of examples 1-17, further comprising one or more floor electrodes disposed on the planar surface of the substrate and located between the first wall and the second wall.

Example 19. The apparatus of example 18, wherein at least one of the floor electrodes is spaced apart and electrically isolated from the plurality of electrodes disposed on the first wall and the second wall.

Example 20. The apparatus of any one of examples 18-19, wherein at least one of the floor electrodes is integrated with and electrically connected to at least one of the plurality of electrodes disposed on the first wall or the second wall.

Example 21. The apparatus of any one of examples 18-20, wherein the plurality of electrodes comprise a first base electrode at least partially disposed on the first wall and a second base electrode at least partially disposed on the second wall.

Example 22. The apparatus of example 21, wherein the one or more floor electrodes comprises a center electrode located at a mid-portion between the first wall and the second wall, a first flank electrode located between the first base electrode and the center electrode, and a second flank electrode located between the second base electrode and the center electrode.

Example 23. The apparatus of example 22, wherein the first flank electrode and the second flank electrode have the same electrode width.

Example 24. The apparatus of any one of examples 22-23, wherein the first base electrode, the second base electrode, and the center electrode are DC electrodes, wherein the first flank electrode and the second flank electrode are RF electrodes.

Example 25. The apparatus of any one of examples 22-23, wherein the first base electrode, the second base electrode, and the center electrode are RF electrodes, wherein the first flank electrode and the second flank electrode are DC electrodes.

Example 26. The apparatus of example 21, wherein the plurality of electrodes comprises a first middle electrode positioned on top of the first base electrode, a first top electrode positioned on top of the first middle electrode, a second middle electrode positioned on top of the second base electrode, a second top electrode positioned on top of the second middle electrode, wherein the one or more floor electrodes are connected to the first and second base electrodes so as to define a unitary base electrode extending from the first wall to the second wall.

Example 27. The apparatus of example 26, wherein the first and second top electrodes have about the same height as the first and second base electrodes.

Example 28. The apparatus of any one of examples 26-27, wherein the first and second middle electrodes have about the same height as the first and second base electrodes.

Example 29. The apparatus of any one of examples 26-27, wherein the first and second middle electrodes have a larger height than the first and second base electrodes.

Example 30. The apparatus of any one of examples 26-27, wherein the first and second middle electrodes have a smaller height than the first and second base electrodes.

Example 31. The apparatus of any one of examples 26-30, wherein the first and second top electrodes and the first and second base electrodes are DC electrodes, wherein the first and second middle electrodes are RF electrodes.

Example 32. The apparatus of any one of examples 26-30, wherein the first and second top electrodes and the first and second base electrodes are RF electrodes, wherein the first and second middle electrodes are DC electrodes.

Example 33. The apparatus of example 21, wherein the one or more floor electrodes comprises a first side electrode that is closer to the first base electrode than the second base electrode and a second side electrode that is closer to the second base electrode than the first base electrode.

Example 34. The apparatus of example 33, wherein the first side electrode and the second side electrode have the same electrode width.

Example 35. The apparatus of any one of examples 33-34, wherein the first base electrode and the second side electrode are DC electrodes, wherein the second base electrode and the first side electrode are RF electrodes.

Example 36. The apparatus of example 21, wherein the plurality of electrodes comprises a first top electrode positioned on top of the first base electrode and a second top electrode positioned on top of the second base electrode, wherein the one or more floor electrodes comprises a planar portion of the first base electrode extending from the first wall toward to second wall and a planar portion of the second base electrode extending from the second wall toward the first wall.

Example 37. The apparatus of example 36, wherein the planar portion of the first base electrode and the planar portion of the second base electrode have about the same width.

Example 38. The apparatus of any one of examples 36-37, wherein the first and second top electrodes have about the same height as the first and second base electrodes.

Example 39. The apparatus of any one of examples 36-37, wherein the first and second top electrodes have a larger height than the first and second base electrodes.

Example 40. The apparatus of any one of examples 36-37, wherein the first and second top electrodes have a smaller height than the first and second base electrodes.

Example 41. The apparatus of any one of examples 36-40, wherein the first base electrode and the second top electrodes are DC electrodes, wherein the second base electrode and the first top electrodes are RF electrodes.

Example 42. The apparatus of any one of examples 1-41, wherein the first wall and the second wall comprise a dielectric material.

Example 43. The apparatus of example 42, wherein the dielectric material comprises organically modified ceramic.

Example 44. The apparatus of example 43, wherein the organically modified ceramic is formulated to have a relative permittivity between 2 and 4, a loss tangent between 0.003 and 0.005, a dielectric strength between 7×105 and 10×105 V/cm, a bulk resistivity between 3×1016 and 5×1016 Ω·cm, and a thermal conductivity between 2 and 3 W/m·K, all inclusive.

Example 45. The apparatus of any one of examples 42-44, wherein the plurality of electrodes comprise a metal selected from the group consisting of gold, platinum, titanium, silver, copper, and aluminum.

Example 46. The apparatus of any one of examples 1-45, wherein the wall height is greater than 25 μm.

Example 47. The apparatus of example 46, wherein the wall height is between 50 μm and 1 mm, inclusive.

Example 48. The apparatus of any one of examples 1-47, wherein each of the first wall and the second wall has a wall width ranging between 50 μm and 1 mm, inclusive.

Example 49. The apparatus of any one of examples 1-48, further comprising a gap between the first wall and the second wall exposing at least a portion of the substrate.

Example 50. The apparatus of any one of examples 1-49, wherein a vertical distance from the trapping position to the planar surface is larger than a distance between the trapping position and the first wall or between the trapping position and the second wall measured along the first axis.

Example 51. An apparatus, comprising: a 3D structure disposed on a planar surface of a substrate; and a plurality of electrodes coated on the 3D structure, wherein the 3D structure comprises an organically modified ceramic material.

Example 52. The apparatus of example 51, wherein the plurality of electrodes comprise a metal selected from the group consisting of gold, platinum, titanium, silver, copper, and aluminum.

Example 53. The apparatus of any one of examples 51-52, wherein the 3D structure comprises a first wall and a second wall extending vertically above the planar surface of the substrate to a wall height, wherein the planar surface of the substrate defines a floor of the 3D structure extending between the first wall and the second wall.

Example 54. The apparatus of example 53, wherein the plurality of electrodes comprises one or more floor electrodes disposed on the floor of the 3D structure.

Example 55. The apparatus of example 54, wherein the plurality of electrodes comprises one or more electrodes at least partially coated on the first wall and one or more electrodes at least partially coated on the second wall.

Example 56. The apparatus of example 55, wherein at least one of the floor electrodes is spaced apart and electrically isolated from the electrodes coated on the first wall and the second wall.

Example 57. The apparatus of any one of examples 55-56, wherein at least one of the floor electrodes is integrated with and electrically connected to at least one of the electrodes coated on the first wall or the second wall.

Example 58. The apparatus of any one of examples 53-57, wherein the floor of the 3D structure has a trap width measured along an axis of the planar surface, the axis being perpendicular to the first and second walls, wherein the wall height is at least 50% of the trap width.

Example 59. The apparatus of example 58, wherein the wall height is equal to or greater than the trap width.

Example 60. The apparatus of any one of examples 53-59, wherein the plurality of electrodes are configured to generate an electric field to trap an ion at a trapping position located between the first wall and the second wall, wherein a vertical distance between the trapping position and the planar surface of the substrate is smaller than the wall height.

Example 61. The apparatus of example 60, wherein the plurality of electrodes comprises one or more DC electrodes configured to generate a DC component of the electric field and one or more RF electrodes configured to generate an RF component of the electric field.

Example 62. The apparatus of example 61, wherein the one or more DC electrodes are configured to be symmetric about the trapping position along the axis, wherein the one or more RF electrodes are also configured to be symmetric about the trapping position along the axis.

Example 63. The apparatus of example 62, wherein the number of DC electrodes is more than the number of RF electrodes.

Example 64. The apparatus of example 62, wherein the number of RF electrodes is more than the number of DC electrodes.

Example 65. The apparatus of example 61, wherein the number of DC electrodes is the same as the number of RF electrodes.

Example 66. The apparatus of example 65, wherein the one or more DC electrodes and the one or more RF electrodes are configured to be symmetric about the trapping position along the axis.

Example 67. The apparatus of any one of examples 65-66, wherein the one or more DC electrodes are configured to be asymmetric about the trapping position along the axis, wherein the one or more RF electrodes are also configured to be asymmetric about the trapping position along the axis.

Example 68. The apparatus of any one of examples 53-67, wherein the first wall is coated by a first electrode extending vertically through the entire wall height, wherein the second wall is coated by a second electrode extending vertically through the entire wall height.

Example 69. The apparatus of any one of examples 53-67, wherein the first wall is coated by two or more stacked first electrodes that are electrically isolated from one another, wherein the second wall is coated by two or more stacked second electrodes that are electrically isolated from one another.

Example 70. The apparatus of example 69, wherein the two or more stacked first electrodes comprise at least one DC electrode and at least one RF electrode, wherein the two or more stacked second electrodes comprise at least one DC electrode and at least one RF electrode.

Example 71. An ion trap assembly, comprising a photopolymerized dielectric material coated with a metal.

Example 72. The ion trap assembly of example 71, wherein the photopolymerized dielectric material comprises organically modified ceramic.

Example 73. The ion trap assembly of any one of examples 71-72, wherein the metal is selected from the group consisting of gold, platinum, titanium, silver, copper, and aluminum.

Example 74. The ion trap assembly of any one of examples 71-73, wherein the photopolymerized dielectric material forms a 3D structure disposed on a planar surface of a substrate.

Example 75. The ion trap assembly of example 74, wherein the 3D structure has a height-to-width ratio that is greater than 0.5.

Example 76. The ion trap assembly of any one of examples 74-75, wherein the 3D structure defines a trench between two opposing walls, wherein the metal is configured to form a plurality of electrodes configured to trap an ion within the trench.

Example 77. The ion trap assembly of example 76, wherein the plurality of electrodes comprises at least two DC electrodes and at least two RF electrodes.

Example 78. An apparatus, comprising: a photolithographic substrate; a 3D-printed 3D structure extending from the photolithographic substrate to define an ion trap volume with an open aperture; and electrodes arranged on selected surfaces of the 3D structure, wherein the ion trap volume is configured to receive at least one ion through the open aperture and the electrodes are configured to produce an electric field that traps the at least one iron within the ion trap volume.

Example 79. The apparatus of example 78, wherein the 3D-printed 3D structure comprises a photopolymerized dielectric material.

Example 80. The apparatus of any one of examples 78-79, wherein the open aperture has a width ranging between 50 μm and 2 mm, inclusive, wherein the ion trap volume has a height ranging between 25 μm and 1 mm, inclusive.

Example 81. An apparatus, comprising: a photolithographic substrate; a 3D-printed 3D structure extending from the photolithographic substrate to define an ion trap volume with an open aperture; and a metallization layer arranged on the 3D structure to define electrodes on selected surfaces of the 3D structure, wherein the electrodes are configured to trap one or more ions within the ion trap volume.

Example 82. The apparatus of example 81, wherein the electrodes are configured to face the interior of the ion trap volume.

Example 83. The apparatus of any one of examples 81-82, wherein the 3D structure comprises at least two walls, wherein the ion trap volume is between the two walls and above the substrate.

Example 84. The apparatus of example 83, wherein at least some of the electrodes are disposed on the two walls.

Example 85. The apparatus of example 84, wherein the electrodes disposed on the two walls are stacked in multiple layers.

Example 86. The apparatus of any one of examples 83-85, wherein at least some of the electrodes are disposed on the photolithographic substrate and between the two walls.

Example 87. The apparatus of any one of examples 81-86, wherein at least some of the electrodes are supplied with DC voltages and at least some of the electrodes are supplied with RF voltages.

Example 88. An apparatus, comprising: a substrate; a 3D-printed wall structure extending from the substrate to form an ion trap volume; and a plurality of electrodes arranged on interior facing surfaces of the wall structure, wherein the electrodes are configured to trap an ion within the ion trap volume with an electric field.

Example 89. A qubit gate comprising any one of the apparatuses of examples 1-88.

Example 90. A quantum computing device comprising one or more qubit gates according to example 89.

Example 91. A device, comprising: a substrate; and an ion trap assembly disposed on the substrate, wherein the ion trap assembly is any one of the apparatuses of examples 1-88.

Example 92. The device of example 91, wherein the substrate comprises a material selected from the group consisting of glass, silicon, polyamide, sapphire, and aluminum nitride.

Example 93. The device of any one of examples 91-92, at least some of the plurality of electrodes are connected to electrical routing wires embedded in the substrate.

Example 94. The device of example 93, wherein the substrate comprises one or more through-wafer vias connected to the at least some of the electrical routing wires.

Example 95. The device of any one of examples 91-94, further comprising one or more active CMOS electronics embedded in the substrate and electrically connected to the ion trap assembly.

Example 96. The device of any one of examples 91-95, further comprising at least one optical waveguide embedded in the substrate and extending underneath the ion trap assembly.

Example 97. The device of example 96, further comprising a grating coupler connected to a terminal end of the at least one optical waveguide and configured to redirect a light traveling through the at least one optical waveguide into a space between the first wall and the second wall of the ion trap assembly.

Example 98. The device of any one of examples 91-97, further comprising at least one photon detector embedded in the substrate and configured to detect photons emitted from the ion.

Example 99. The device of any one of examples 91-98, wherein the ion trap assembly is one of a plurality of ion trap assemblies disposed on the substrate.

Example 100. The device of example 99, wherein the plurality of ion trap assemblies are arranged to form an ion trap grid defined by a plurality of rows intersecting with a plurality of columns, wherein spaces between first and second walls of respective ion trap assemblies are interconnected to form a grid of trenches along the plurality of rows and the plurality of columns.

Example 101. A method, comprising: preparing a substrate; printing a 3D structure on the substrate; and selectively coating the 3D structure with a metal to form a plurality of electrodes, wherein printing the 3D structure comprises printing a first wall and a second wall extending vertically above a planar surface of the substrate to a wall height, wherein selectively coating the 3D structure comprises coating at least one electrode on the first wall and coating at least one electrode on the second wall.

Example 102. The method of example 101, wherein printing the 3D structure comprises printing a dielectric material layer by layer using two-photon direct laser writing lithography.

Example 103. The method of example 102, wherein the dielectric material comprises organically modified ceramic.

Example 104. The method of any one of examples 101-103, wherein the wall height is equal to or greater than a width between the first wall and the second wall.

Example 105. The method of any one of examples 101-104, wherein printing the 3D structure comprises forming one or more horizontal gaps on the first wall and the second wall, wherein the horizontal gaps are parallel to the substrate.

Example 106. The method of any one of examples 101-105, wherein printing the 3D structure comprises forming one or more vertical gaps on the first wall and the second wall, wherein the vertical gaps are perpendicular to the substrate.

Example 107. The method of any one of examples 101-106, wherein preparing the substrate comprises sputtering a sacrificial layer on top of the substrate.

Example 108. The method of example 107, wherein the sacrificial layer comprises a metal selected from the group consisting of aluminum and chromium, and copper.

Example 109. The method of any one of examples 107-108, wherein preparing the substrate comprises depositing a positive photoresist layer on top of the sacrificial layer.

Example 110. The method of example 109, wherein preparing the substrate comprises photopatterning one or more traces on the positive photoresist layer, wherein the one or more traces define at least a top contour of the 3D structure.

Example 111. The method of example 110, wherein the one or more traces further define at least one metal trace on the substrate, wherein the at least one metal trace is connected to a portion of the 3D structure where an electrode is formed.

Example 112. The method of any one of examples 110-111, wherein preparing the substrate comprises exposing the positive photoresist layer to a developer solution so as to remove portions of the positive photoresist layer defined by the one or more traces, thereby exposing portions of the sacrificial layer underneath the removed portions of the positive photoresist layer.

Example 113. The method of example 112, wherein preparing the substrate comprises etching away the exposed portions of the sacrificial layer.

Example 114. The method of any one of examples 107-113, further comprising lifting off the sacrificial layer which remains on the substrate after coating the 3D structure.

Example 115. The method of any one of examples 101-114, wherein selectively coating the 3D structure comprises selectively coating a trench floor of the 3D structure, wherein the trench floor of the 3D structure is defined by a top surface of the substrate extending between the first wall and the second wall.

Example 116. The method of example 115, wherein selectively coating the trench floor comprises forming one or more floor electrodes on the trench floor.

Example 117. The method of example 116, wherein selectively coating the trench floor comprises forming at least one gap between the one or more floor electrodes so as to expose the substrate underneath the gap.

Example 118. The method of any one of examples 116-117, wherein selectively coating the trench floor comprises electrically isolating at least one of the floor electrodes from the electrodes disposed on the first wall and the second wall.

Example 119. The method of any one of examples 116-118, wherein selectively coating the trench floor comprises electrically coupling at least one of the floor electrodes to at least one of the electrodes disposed on the first wall or the second wall.

Example 120. The method of any one of examples 101-119, wherein selectively coating the 3D structure comprises forming a first electrode on the first wall and forming a second electrode on the second wall, wherein the first and second electrodes extend vertically through the entire wall height of the respective first and second walls.

Example 121. The method of any one of examples 101-119, wherein selectively coating the 3D structure comprises forming two or more stacked first electrodes on the first wall and forming two or more stacked second electrodes on the second wall, wherein the two or more stacked first electrodes are electrically isolated from one another and the two or more stacked second electrodes are electrically isolated from one another.

Example 122. The method of any one of examples 101-121, wherein selectively coating the 3D structure comprises coating one or more metal traces on the substrate, wherein the one or more metal traces are connected to at least some of the plurality of electrodes.

Example 123. The method of any one of examples 101-122, wherein selectively coating the 3D structure comprises applying electron beam evaporation to deposit the metal on selected portions of the 3D structure.

Example 124. The method of any one of examples 101-123, wherein selectively coating the 3D structure comprises applying angle evaporation to deposit the metal on selected portions of the 3D structure.

Example 125. The method of any one of examples 101-124, wherein printing the 3D structure comprises forming at least one gap on the first wall or the second wall, wherein selectively coating the 3D structure comprises adjusting a deposition direction of the metal so that at least a portion of an inside wall of the gap is not coated by the metal, thereby creating an electrical insulation between metals coated on opposite sides of the gap.

Example 126. The method of any one of examples 101-125, wherein the metal is selected from the group consisting of gold, platinum, titanium, silver, copper, and aluminum.

Example 127. The method of any one of examples 101-126, further comprising connecting at least one of the plurality of electrodes to a DC voltage source.

Example 128. The method of any one of examples 101-127, further comprising connecting at least one of the plurality of electrodes to an RF voltage source.

### EXAMPLE ALTERNATIVES

The technologies from any example can be combined with the technologies described in any one or more of the other examples. In view of the many possible examples to which the principles of the disclosed technology can be applied, it should be recognized that the illustrated embodiments are examples of the disclosed technology and should not be taken as a limitation on the scope of the disclosed technology. Rather, the scope of the claimed subject matter is defined by the following claims and their equivalents.

1. An apparatus, comprising:
a first wall and a second wall extending from a planar surface of a substrate to a wall height; and
a plurality of electrodes disposed on the first wall and the second wall,
wherein the first wall and the second wall are spaced apart from one another along a first axis on the planar surface,
wherein the plurality of electrodes are configured to generate an electric field to trap an ion at a trapping position located between the first wall and the second wall, wherein a vertical distance between the trapping position and the planar surface of the substrate is smaller than the wall height.

2. The apparatus of claim 1, wherein the plurality of electrodes comprises one or more direct current (DC) electrodes configured to generate a DC component of the electric field and one or more radial frequency (RF) electrodes configured to generate an RF component of the electric field.

3-5. (canceled)

6. The apparatus of claim 1, wherein the first wall and the second wall extend along a second axis on the planar surface of the substrate, the second axis being perpendicular to the first axis.

7. The apparatus of claim 6, wherein a length of the first wall and the second wall measured along the second axis is larger than a width between the first wall and the second wall measured along the first axis.

8. (canceled)

9. The apparatus of claim 6, wherein each of the first wall and the second wall comprises a plurality of segmented portions along the second axis, wherein a plurality of DC electrodes that are electrically insulated from each other are disposed on respective segmented portions.

10. The apparatus of claim 6, wherein the trapping position is located on a trapping axis, wherein the trapping axis extends parallel to the second axis is located halfway between the first wall and the second wall.

11. The apparatus of claim 1, wherein an inner surface of the first wall faces an inner surface of the second wall, wherein the inner surface of the first wall and the inner surface of the second wall are perpendicular to the planar surface of the substrate.

12. The apparatus of claim 11, wherein each of the inner surface of the first wall and the inner surface of the second wall comprises one or more cuts extending parallel to the planar surface of the substrate, wherein each cut separates at least one upper electrode above the cut and at least one lower electrode below the cut, wherein the at least one upper electrode is electrically insulated from the at least one lower electrode.

13-46. (canceled)

47. The apparatus of claim 1, wherein the wall height is between 50 μm and 1 mm, inclusive.

48. The apparatus of claim 1, wherein each of the first wall and the second wall has a wall width ranging between 50 μm and 1 mm, inclusive.

49-50. (canceled)

51. An apparatus, comprising:
a 3D structure disposed on a planar surface of a substrate; and
a plurality of electrodes coated on the 3D structure,
wherein the 3D structure comprises an organically modified ceramic material.

52. (canceled)

53. The apparatus of claim 51, wherein the 3D structure comprises a first wall and a second wall extending vertically above the planar surface of the substrate to a wall height, wherein the planar surface of the substrate defines a floor of the 3D structure extending between the first wall and the second wall.

54-57. (canceled)

58. The apparatus of claim 53, wherein the floor of the 3D structure has a trap width measured along an axis of the planar surface, the axis being perpendicular to the first and second walls, wherein the wall height is at least 50% of the trap width.

59. (canceled)

60. The apparatus of claim 53, wherein the plurality of electrodes are configured to generate an electric field to trap an ion at a trapping position located between the first wall and the second wall, wherein a vertical distance between the trapping position and the planar surface of the substrate is smaller than the wall height.

61-67. (canceled)

68. The apparatus of claim 53, wherein the first wall is coated by a first electrode extending vertically through the entire wall height, wherein the second wall is coated by a second electrode extending vertically through the entire wall height.

69. The apparatus of claim 53, wherein the first wall is coated by two or more stacked first electrodes that are electrically isolated from one another, wherein the second wall is coated by two or more stacked second electrodes that are electrically isolated from one another.

70. The apparatus of claim 69, wherein the two or more stacked first electrodes comprise at least one DC electrode and at least one RF electrode, wherein the two or more stacked second electrodes comprise at least one DC electrode and at least one RF electrode.

71-77. (canceled)

78. An apparatus, comprising:
a photolithographic substrate;
a 3D-printed 3D structure extending from the photolithographic substrate to define an ion trap volume with an open aperture; and
electrodes arranged on selected surfaces of the 3D structure, wherein the ion trap volume is configured to receive at least one ion through the open aperture and the electrodes are configured to produce an electric field that traps the at least one ion within the ion trap volume.

79. The apparatus of claim 78, wherein the 3D-printed 3D structure comprises a photopolymerized dielectric material.

80. The apparatus of claim 78, wherein the open aperture has a width ranging between 50 μm and 2 mm, inclusive, wherein the ion trap volume has a height ranging between 25 μm and 1 mm, inclusive.

81-128. (canceled)
